(19) United States
(12) Patent Application Publication
(10) Pub. No.: US 2011/0143279 A1
(43) Pub. Date: Jun. 16, 2011

(54) RADIATION-SENSITIVE RESIN COMPOSITION

(75) Inventors: Tsutomu SHIMOKAWA, Tokyo (JP); Takuma Ebata, Tokyo (JP); Kaori Sakai, Tokyo (JP); Yoshifumi Oizumi, Tokyo (JP); Akimasa Soyano, Tokyo (JP); Noboru Otsuka, Tokyo (JP)

(73) Assignee: JSR Corporation, Tokyo (JP)

(21) Appl. No.: 13/005,539

(22) Filed: Jan. 13, 2011

Related U.S. Application Data
(63) Continuation of application No. PCT/JP2009/062697, filed on Jul. 13, 2009.

(30) Foreign Application Priority Data
Jul. 14, 2008 (JP) 2008-182274
Sep. 18, 2008 (JP) 2008-238962
Mar. 27, 2009 (JP) 2009-079446

(51) Int. Cl. G03F 7/004

(52) U.S. Cl. 430/270.1

(57) ABSTRACT

A radiation-sensitive resin composition includes a sulfonate or sulfonic acid group-containing photoacid generator and a resin. The sulfonate or sulfonic acid group-containing photoacid generator includes a partial structure shown by a following formula (1),

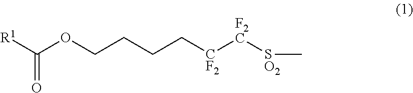

wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms that include a hetero atom.

### CROSS-REFERENCE TO RELATED APPLICATIONS

The present application is a continuation application of International Application No. PCT/JP2009/062697, filed Jul. 13, 2009, which claims priority to Japanese Patent Application No. 2008-182274, filed Jul. 14, 2008, Japanese Patent Application No. 2008-238962, filed Sep. 18, 2008, and Japanese Patent Application No. 2009-079446, filed Mar. 27, 2009. The contents of these applications are incorporated herein by reference in their entirety.

### BACKGROUND OF THE INVENTION

1. Field of the Invention

The present invention relates to a radiation-sensitive resin composition.

2. Discussion of the Background

When applying deep ultraviolet rays (e.g., KrF excimer laser light or ArF excimer laser light) or the like to a chemically-amplified radiation-sensitive resin composition, an acid is generated in the exposed area, and a difference in solubility rate in a developer occurs between the exposed area and the unexposed area due to chemical reactions catalyzed by the generated acid. A resist pattern is formed on a substrate utilizing the difference in solubility rate. See, for example, Japanese Examined Patent Publication (KOKOKU) No. 2-27660.

A photoacid generator included in the chemically-amplified radiation-sensitive resin composition is required to exhibit excellent transparency to radiation and have a high quantum yield when generating an acid. The acid generated by the photoacid generator is required to have sufficient acidity, a sufficiently high boiling point, and an appropriate diffusion distance (hereinafter may be referred to as “diffusion length”) within the resist film.

When using an ionic photoacid generator, the structure of the anion moiety is important in order to obtain sufficient acidity, a sufficiently high boiling point, and an appropriate diffusion length. When using a nonionic photoacid generator having a sulfonyl structure or a sulfonate structure, the structure of the sulfonyl moiety is important.

For example, a photoacid generator having a trifluoromethanesulfonyl structure generates an acid having sufficient acidity, and sufficiently increases the resolution of the photoresist. However, since the acid generated by the photoacid generator having a trifluoromethanesulfonyl structure has a low boiling point and a large diffusion length, the mask dependence of the photoresist increases. A photoacid generator having a sulfonyl structure bonded to a large organic group (e.g., 10-camphorsulfonyl structure) generates an acid having a sufficiently high boiling point and an appropriate diffusion length (i.e., the mask dependence is reduced). However, since the acid generated by such a photoacid generator does not have sufficient acidity, the resolution of the photoresist is insufficient.

A photoacid generator having a perfluoroalkylsulfonyl structure (e.g., perfluoro-n-octanesulfonic acid (PFOS)) has attracted attention since such a photoacid generator generates an acid having sufficient acidity, a sufficiently high boiling point, and an appropriate diffusion length.

However, a report (Perfluorooctyl Sulfonates; Proposed Significant New Use Rule) published by the U.S. Environmental Protection Agency proposes regulating the use of a compound having a perfluoroalkylsulfonyl structure (e.g., PFOS) from the viewpoint of environmental protection due to low combustibility and bioaccumulation.

When precisely controlling the line width (e.g., when the device design dimensions are equal to or less than sub-half micrometers), it is important for a chemically-amplified resist to exhibit an excellent resolution and provide excellent surface flatness. When using a chemically-amplified resist that provides poor surface flatness, elevations and depressions (hereinafter may be referred to as “nano edge roughness”) formed on the surface of the resist film may be transferred to a substrate when transferring the resist pattern to the substrate by etching or the like, so that the dimensional accuracy of the pattern may decrease. This may impair the electrical properties of the resulting device (see J. Photopolym. Sci. Tech., p. 571 (1998), Proc. SPIE, Vol. 3333, p. 313, Proc. SPIE, Vol. 3333, p. 634, and J. Vac. Sci. Technol. B16 (1), p. 69 (1998), for example).

### SUMMARY OF THE INVENTION

According to one aspect of the present invention, a radiation-sensitive resin composition includes a sulfonate or sulfonic acid group-containing photoacid generator and a resin. The sulfonate or sulfonic acid group-containing photoacid generator includes a partial structure shown by a following formula (1),

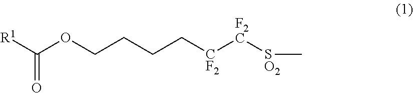

wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms that include a hetero atom.

### DESCRIPTION OF THE EMBODIMENTS

The embodiments of the invention are described below. Note that the embodiments of the invention are not limited to the following embodiments. Various modifications and improvements may be made of the following embodiments without departing from the scope of the invention based on the knowledge of a person having ordinary skill in the art.

### Sulfonate or Sulfonic Acid Group-Containing Photoacid Generator

A radiation-sensitive resin composition according to one embodiment of the invention includes (A) a sulfonate or sulfonic acid group-containing photoacid generator that includes a partial structure shown by the following general formula (1). This radiation-sensitive resin composition includes a photoacid generator that has an excellent function and adversely affects the environment and a human body to only a small extent, and can form a resist film that produces an excellent resist pattern.

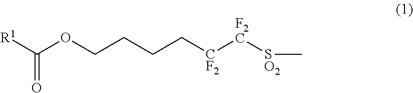

wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms that may include a hetero atom.

Examples of the unsubstituted linear or branched monovalent hydrocarbon group having 1 to 30 carbon atoms include a methyl group, an ethyl group, an n-propyl group, an i-propyl group, an n-butyl group, a t-butyl group, an n-pentyl group, an i-pentyl group, an n-hexyl group, an i-hexyl group, an n-heptyl group, an n-octyl group, an i-octyl group, an n-nonyl group, an n-decyl group, a 2-ethylhexyl group, and an n-dodecyl group.

The above hydrocarbon group may be substituted with a halogen atom (e.g., fluorine atom, chlorine atom, bromine atom, or iodine atom), a hydroxyl group, a thiol group, an aryl group, an alkenyl group, or an organic group that includes a heteroatom (e.g., halogen atom, oxygen atom, nitrogen atom, sulfur atom, phosphorus atom, or silicon atom). The above hydrocarbon group may be substituted with a keto group (i.e., two hydrogen atoms bonded to a single carbon of the hydrocarbon group are substituted with an oxygen atom). The number of substituents is not limited. Examples of the substituted linear or branched monovalent hydrocarbon group having 1 to 30 carbon atoms include a benzyl group, a methoxymethyl group, a methylthiomethyl group, an ethoxymethyl group, a phenoxymethyl group, a methoxycarbonylmethyl group, an ethoxycarbonylmethyl group, an acetylmethyl group, a fluoromethyl group, a trifluoromethyl group, a 2,2,2-trifluoroethyl group, a chloromethyl group, a trichloromethyl group, a 2-fluoropropyl group, a trifluoroacetylmethyl group, a trichloroacetylmethyl group, a pentafluorobenzoylmethyl group, an aminomethyl group, a cyclohexylaminomethyl group, a diphenylphosphinomethyl group, a trimethylsilylmethyl group, a 2-phenylethyl group, a 3-phenylpropyl group, a 2-aminoethyl group, a hydroxymethyl group, a hydroxyethyl group, and a hydroxycarbonylmethyl group.

Examples of the cyclic or partially cyclic monovalent hydrocarbon group having 3 to 30 carbon atoms include a cyclopropyl group, a cyclobutyl group, a cyclopentyl group, a cyclohexyl group, a bornyl group, a norbornyl group, an adamantyl group, a pinanyl group, a thujyl group, a caryl group, a camphanyl group, a cyclopropylmethyl group, a cyclobutylmethyl group, a cyclopentylmethyl group, a cyclohexylmethyl group, a bornylmethyl group, a norbornylmethyl group, and an adamantylmethyl group.

The above hydrocarbon group may be substituted with a halogen atom (e.g., fluorine atom, chlorine atom, bromine atom, or iodine atom), a hydroxyl group, a thiol group, an aryl group, an alkenyl group, or an organic group that includes a heteroatom (e.g., halogen atom, oxygen atom, nitrogen atom, sulfur atom, phosphorus atom, or silicon atom). The above hydrocarbon group may be substituted with a keto group (i.e., two hydrogen atoms bonded to a single carbon of the hydrocarbon group are substituted with an oxygen atom). The number of substituents is not limited.

Examples of the substituted cyclic or partially cyclic monovalent hydrocarbon group having 3 to 30 carbon atoms include a 4-fluorocyclohexyl group, a 4-hydroxycyclohexyl group, a 4-methoxycyclohexyl group, a 4-methoxycarbonylcyclohexyl group, a 3-hydroxy-1-adamantyl group, a 3-methoxycarbonyl-1-adamantyl group, a 3-hydroxycarbonyl-1-adamantyl group, and a 3-hydroxymethyl-1-adamantanemethyl group.

Examples of the aryl group having 6 to 30 carbon atoms include a phenyl group, a 1-naphthyl group, a 2-naphthyl group, a 1-anthryl group, and a 1-phenanthryl group. The aryl group may be substituted with a halogen atom (e.g., fluorine atom, chlorine atom, bromine atom, or iodine atom), a hydroxyl group, a thiol group, an alkyl group, or an organic group that includes a heteroatom (e.g., halogen atom, oxygen atom, nitrogen atom, sulfur atom, phosphorus atom, or silicon atom). Examples of the substituted aryl group having 6 to 30 carbon atoms include an o-hydroxyphenyl group, an m-hydroxyphenyl group, a p-hydroxyphenyl group, a 3,5-bis(hydroxy)phenyl group, an o-tolyl group, an m-tolyl group, a p-tolyl group, a p-methoxyphenyl group, a mesityl group, an o-cumenyl group, a 2,3-xylyl group, an o-fluorophenyl group, an m-fluorophenyl group, a p-fluorophenyl group, an o-trifluoromethylphenyl group, an m-trifluoromethylphenyl group, a p-trifluoromethylphenyl group, a 3,5-bis(trifluoromethyl)phenyl group, a p-bromophenyl group, a p-chlorophenyl group, and a p-iodophenyl group.

Examples of the cyclic monovalent organic group having 4 to 30 carbon atoms that may include a hetero atom include a furyl group, a thienyl group, a pyranyl group, a pyrrolyl group, a thianthrenyl group, a pyrazolyl group, an isothiazolyl group, an isooxazolyl group, a pyrazinyl group, a pyrimidinyl group, a pyridazinyl group, and a monocyclic or polycyclic lactone. Examples of the monocyclic or polycyclic lactone include γ-butyrolactone, γ-valerolactone, angelica lactone, γ-hexylactone, γ-heptalactone, γ-octalactone, γ-nonalactone, 3-methyl-4-octanolide (whisky lactone), γ-decalactone, γ-undecalactone, γ-dodecalactone, γ-jasmolactone (7-decenolactone), δ-hexylactone, 4,6,6(4,4,6)-trimethyltetrahydropyran-2-one, δ-octalactone, δ-nonalactone, δ-decalactone, δ-2-decenolactone, δ-undecalactone, δ-dodecalactone, δ-tridecalactone, δ-tetradecalactone, lactoscatone, ε-decalactone, ε-dodecalactone, cyclohexyllactone, jasmine lactone, cis-jasmone lactone, methyl-γ-decalactone, and lactones shown by the following formulas.

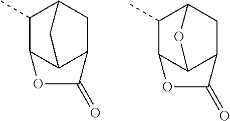

wherein a dotted line indicates a bonding site.

The above cyclic organic group that may include a hetero atom may be substituted with a halogen atom (e.g., fluorine atom, chlorine atom, bromine atom, or iodine atom), a hydroxyl group, a thiol group, an aryl group, an alkenyl group, or an organic group that includes a heteroatom (e.g., halogen atom, oxygen atom, nitrogen atom, sulfur atom, phosphorus atom, or silicon atom). The above cyclic organic group that may include a hetero atom may be substituted with a keto group (i.e., two hydrogen atoms bonded to a single carbon of the cyclic organic group are substituted with an oxygen atom). The number of substituents is not limited.

Examples of the substituted cyclic monovalent organic group having 4 to 30 carbon atoms that may include a hetero atom include a 2-bromofuryl group and a 3-methoxythienyl group.

Specific examples of the structure shown by the general formula (1) are given below.

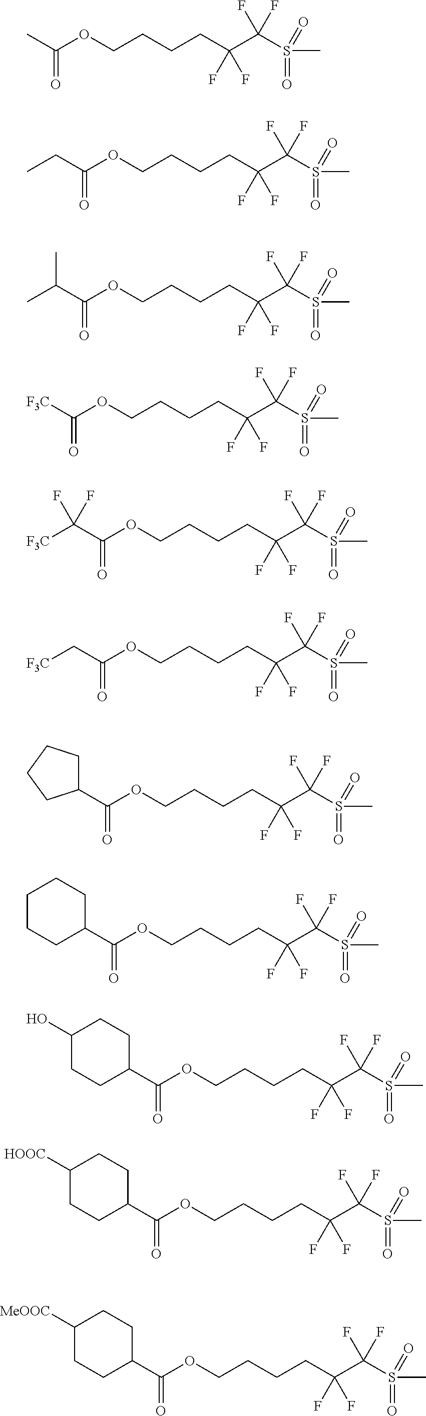

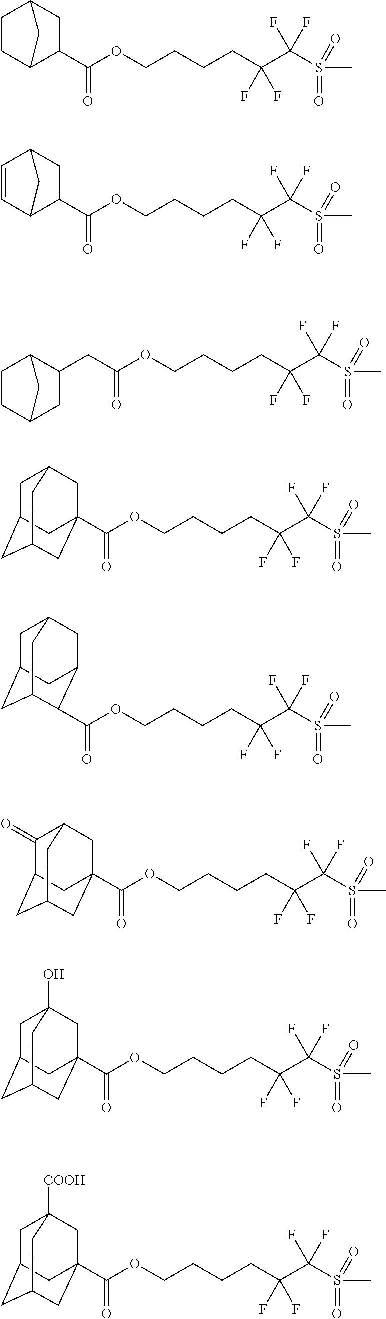

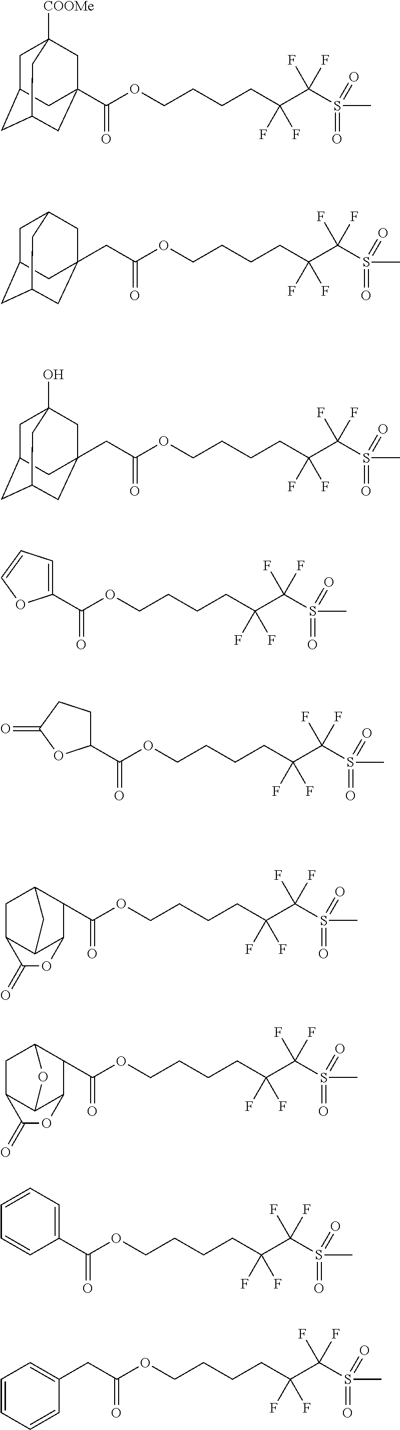

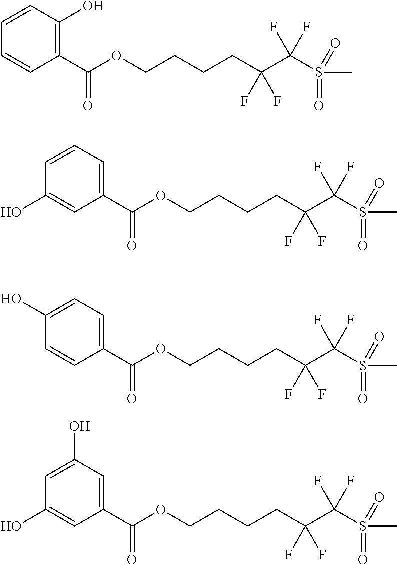

Examples of a preferable sulfonate having a partial structure shown by the general formula (1) include a sulfonate shown by the following general formula (2).

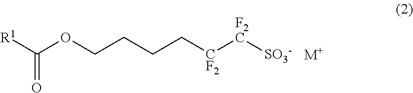

wherein R¹ is the same as defined for the general formula (1), and M⁺ represents a monovalent onium cation.

Examples of the monovalent onium cation include onium cations of O, S, Se, N, P, As, Sb, Cl, Br, and I. Among these, onium cations of S and I are preferable.

Examples of the monovalent onium cation represented by M⁺ include onium cations shown by the following general formulas (3) and (4).

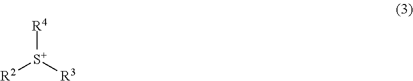

wherein R², R³, and R⁴ individually represent a substituted or unsubstituted linear or branched alkyl group having 1 to 10 carbon atoms or a substituted or unsubstituted aryl group having 6 to 18 carbon atoms, provided that at least two of R², R³, and R⁴ may bond to form a ring with the sulfur atom.

R⁵—I⁺—R⁶ (4)

wherein R⁵ and R⁶ individually represent a substituted or unsubstituted linear or branched alkyl group having 1 to 10 carbon atoms or a substituted or unsubstituted aryl group having 6 to 18 carbon atoms, provided that R⁵ and R⁶ may bond to form a ring with the iodine atom.

The onium cation shown by the general formula (3) is preferably an onium cation shown by the following general formula (3-1) or (3-2), and the onium cation shown by the general formula (4) is preferably an onium cation shown by the following general formula (4-1).

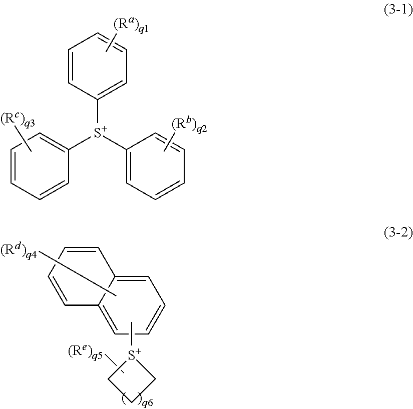

wherein R^{a}, R^{b}, and R^{c} individually represent a hydrogen atom, a substituted or unsubstituted linear or branched alkyl group having 1 to 12 carbon atoms, or a substituted or unsubstituted aryl group having 6 to 12 carbon atoms, provided that at least two of R^{a}, R^{b}, and R^{c} may bond to form a ring, q1, q2, and q3 are individually an integer from 0 to 5, R^{d} individually represent a hydrogen atom, a substituted or unsubstituted linear or branched alkyl group having 1 to 8 carbon atoms, or a substituted or unsubstituted aryl group having 6 to 8 carbon atoms, provided that at least two of R^{d} may bond to form a ring, R^{e} individually represent a hydrogen atom, a substituted or unsubstituted linear or branched alkyl group having 1 to 7 carbon atoms, or a substituted or unsubstituted aryl group having 6 to 7 carbon atoms, provided that at least two of R^{e} may bond to form a ring, q4 is an integer from 0 to 7, q5 is an integer from 0 to 6, and q6 is an integer from 0 to 3.

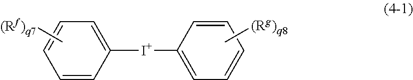

wherein R^{f} and R^{g} individually represent a hydrogen atom, a substituted or unsubstituted linear or branched alkyl group having 1 to 12 carbon atoms, or a substituted or unsubstituted aryl group having 6 to 12 carbon atoms, provided that at least two of R^{f} and R^{g} may bond to form a ring, and q7 and q8 are individually an integer from 0 to 5.

Examples of a preferable sulfonium cation shown by the general formula (3-1) or (3-2) include sulfonium cations shown by the following formulas (i-1) to (i-64). Examples of a preferable iodonium cation shown by the general formula (4-1) include iodonium cations shown by the following formulas (ii-1) to (ii-39).

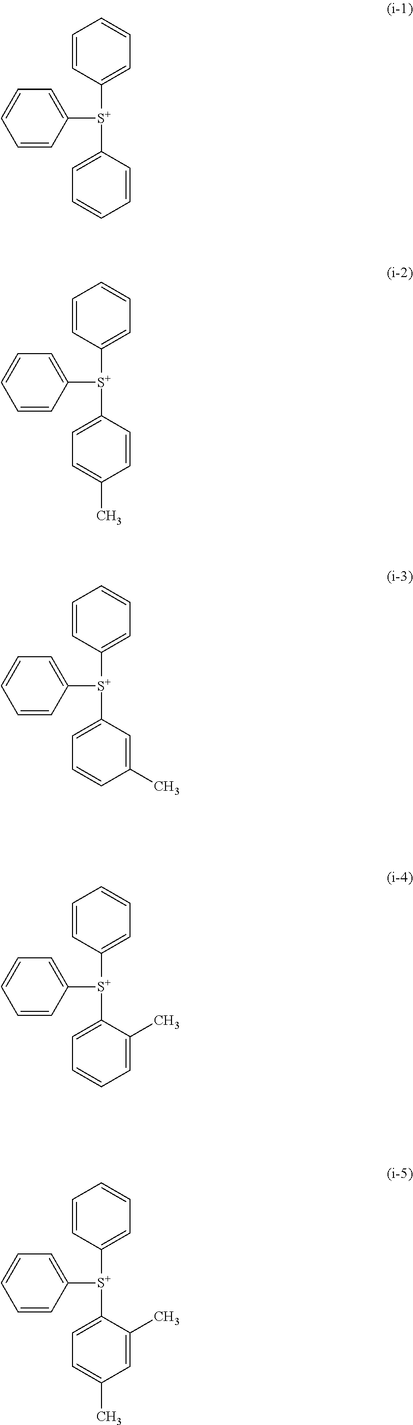

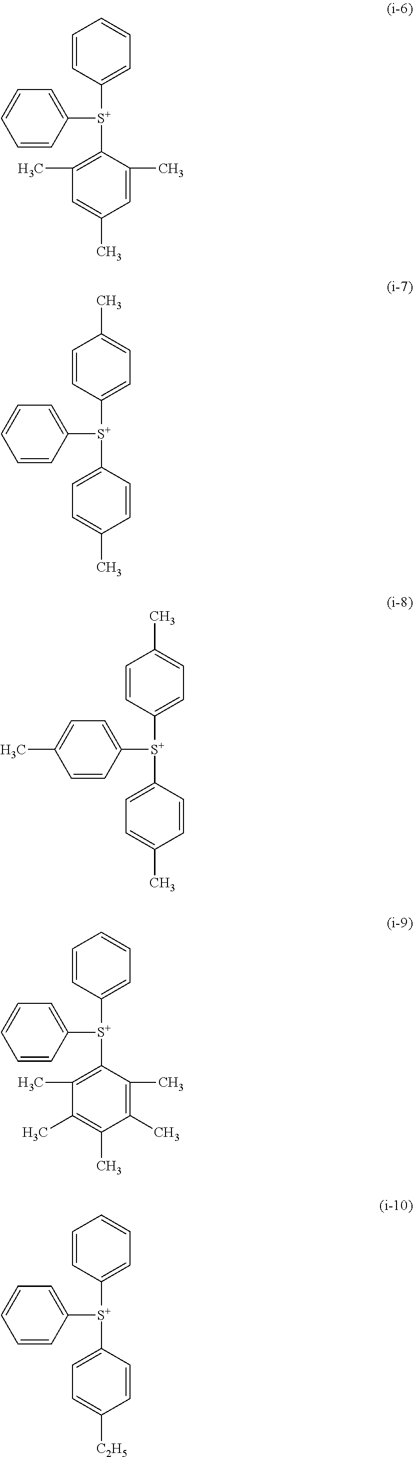

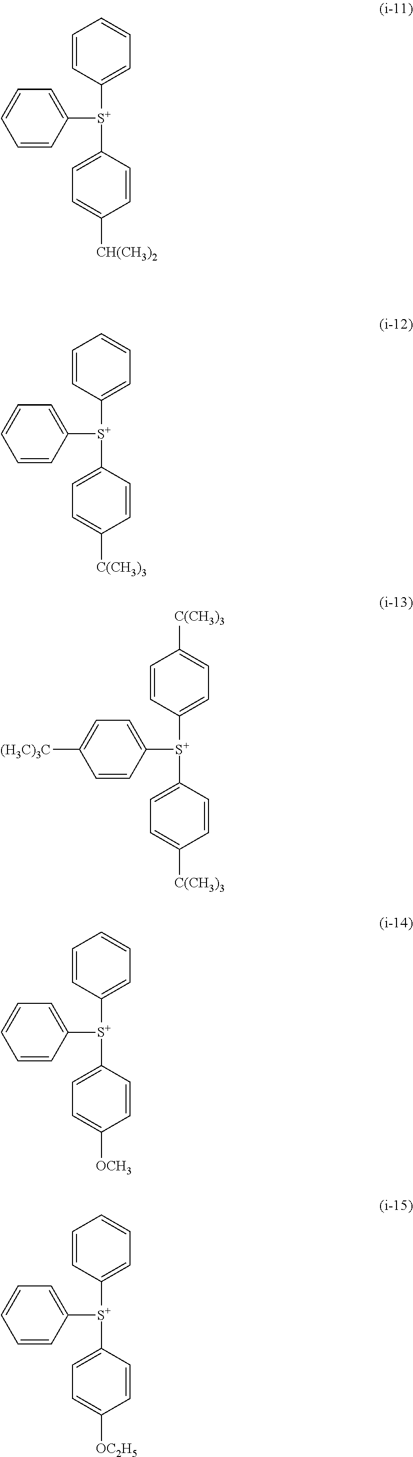

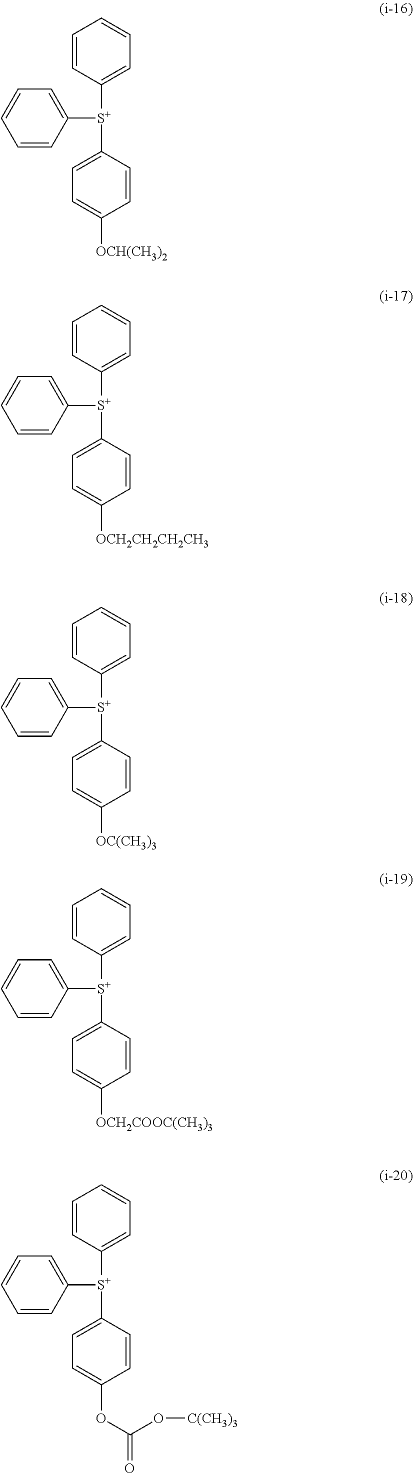

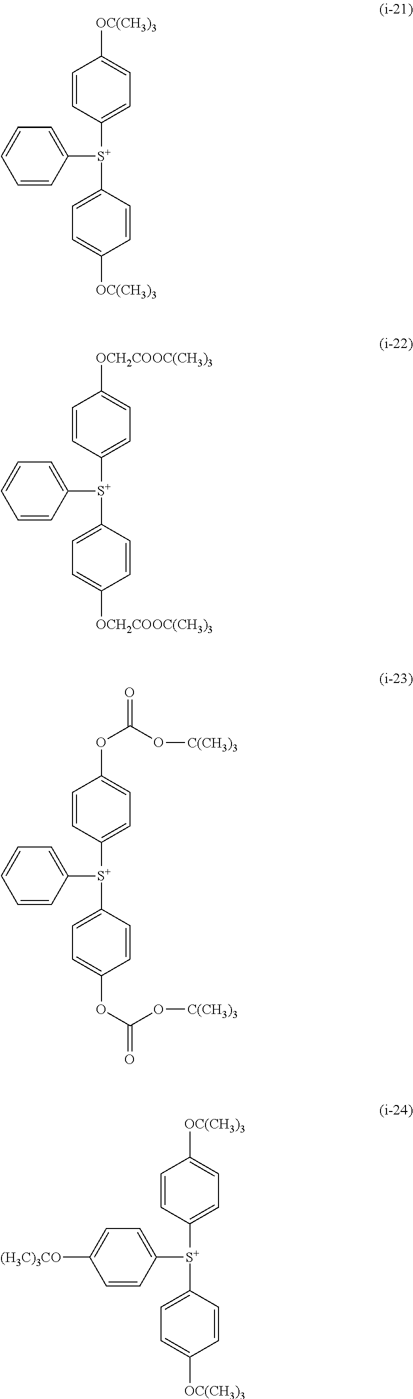

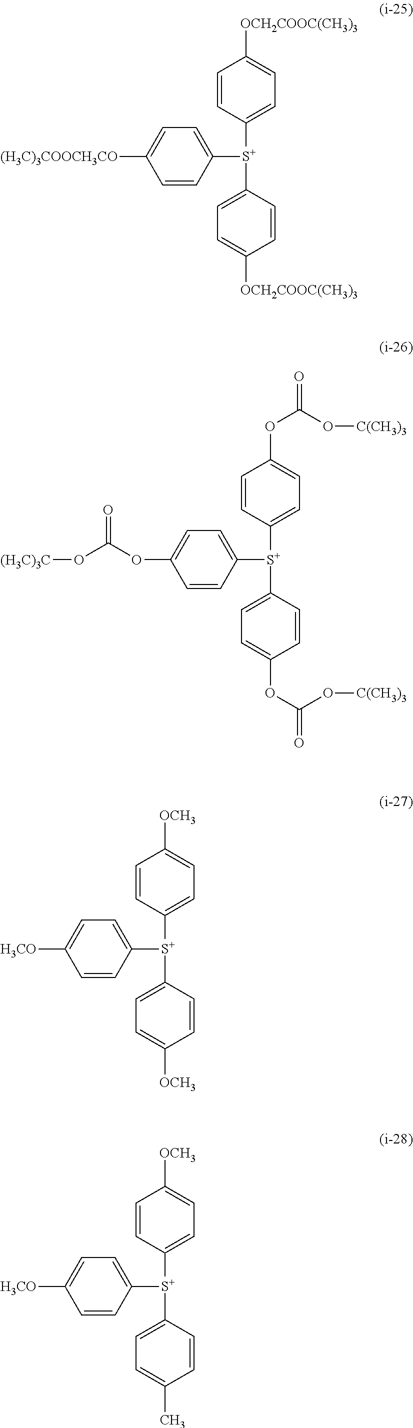

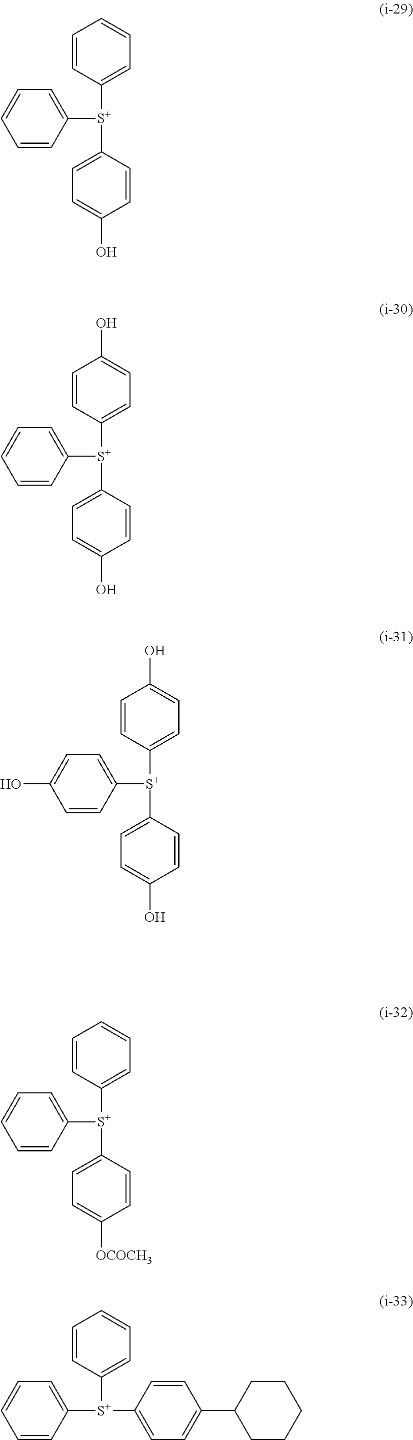

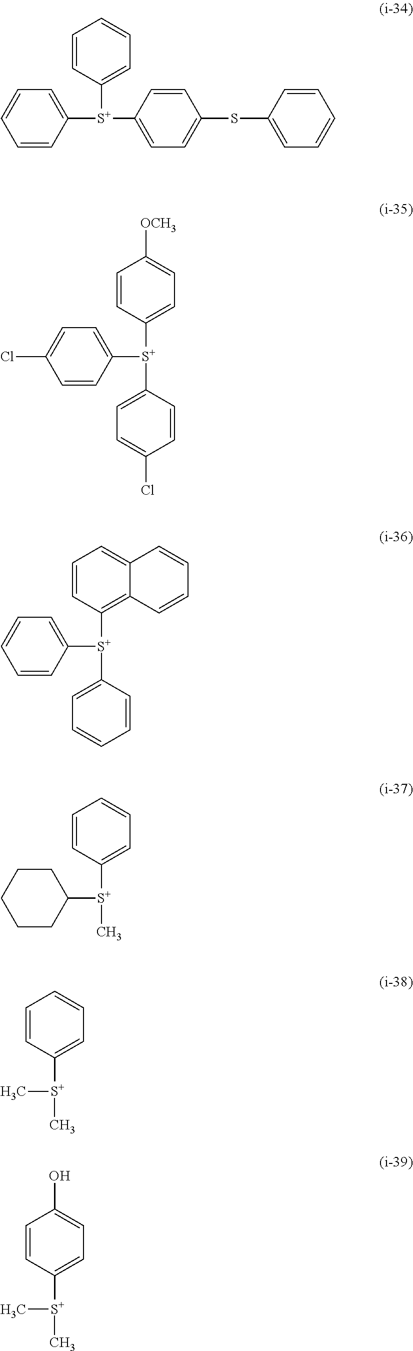

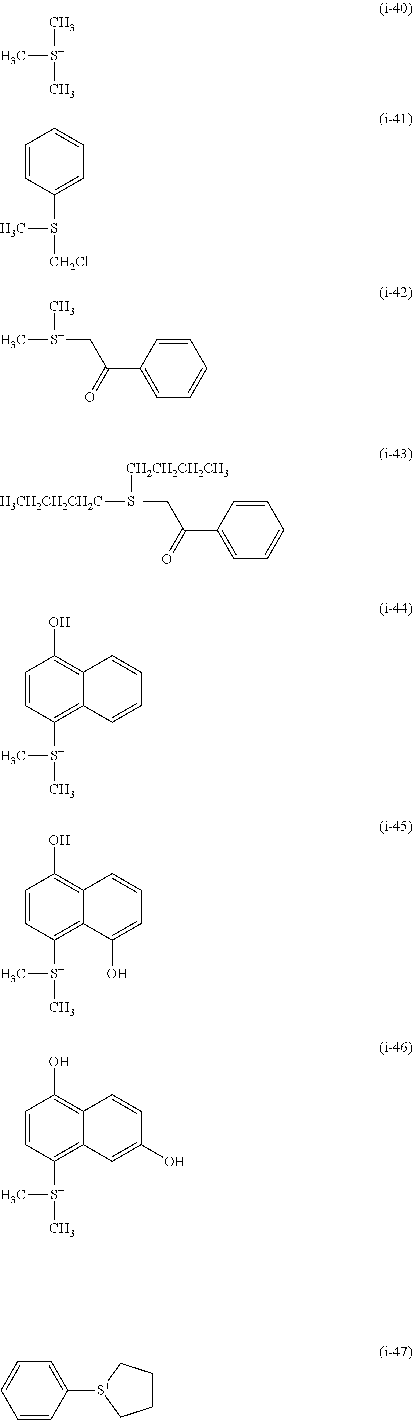

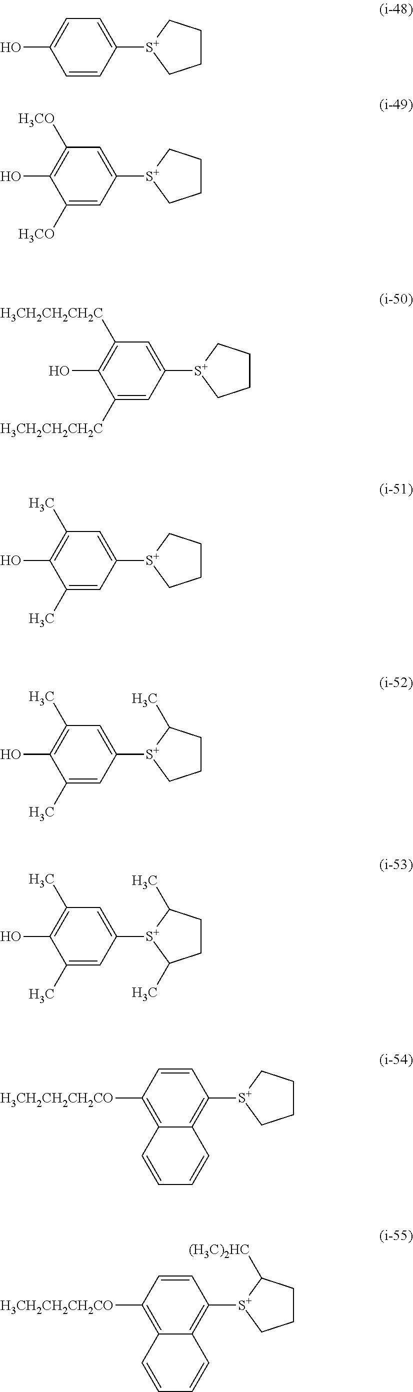

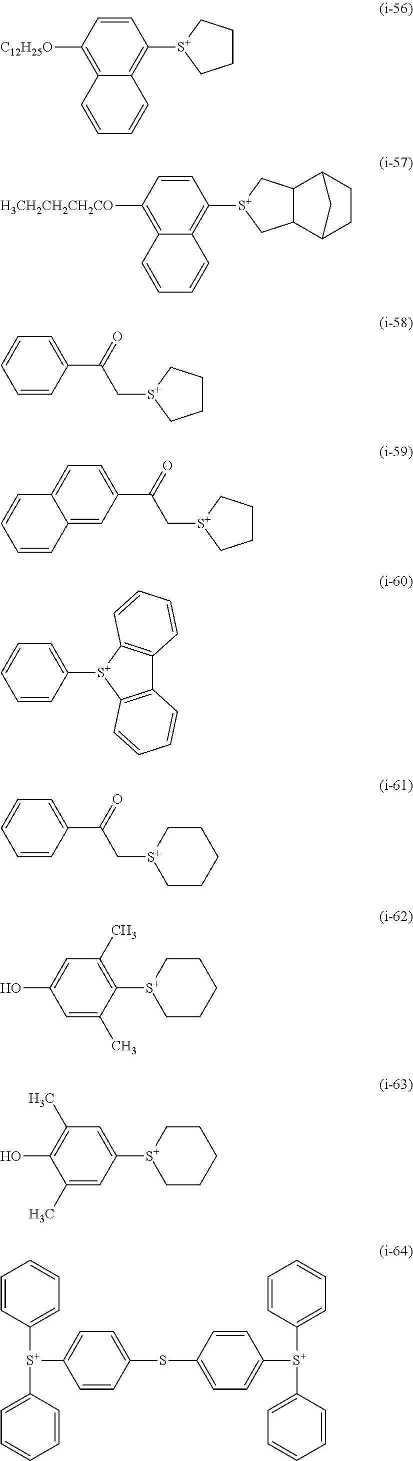

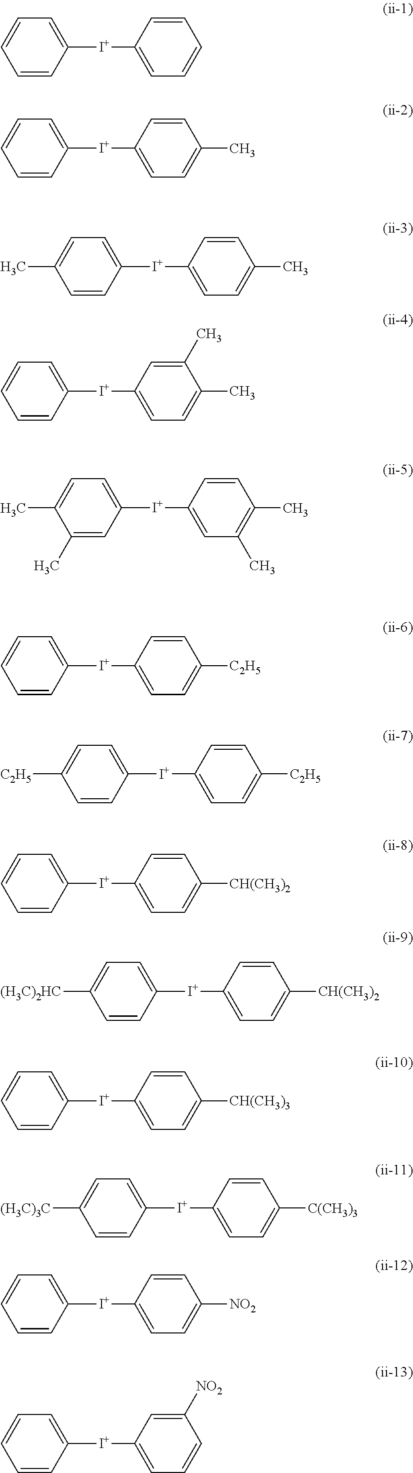

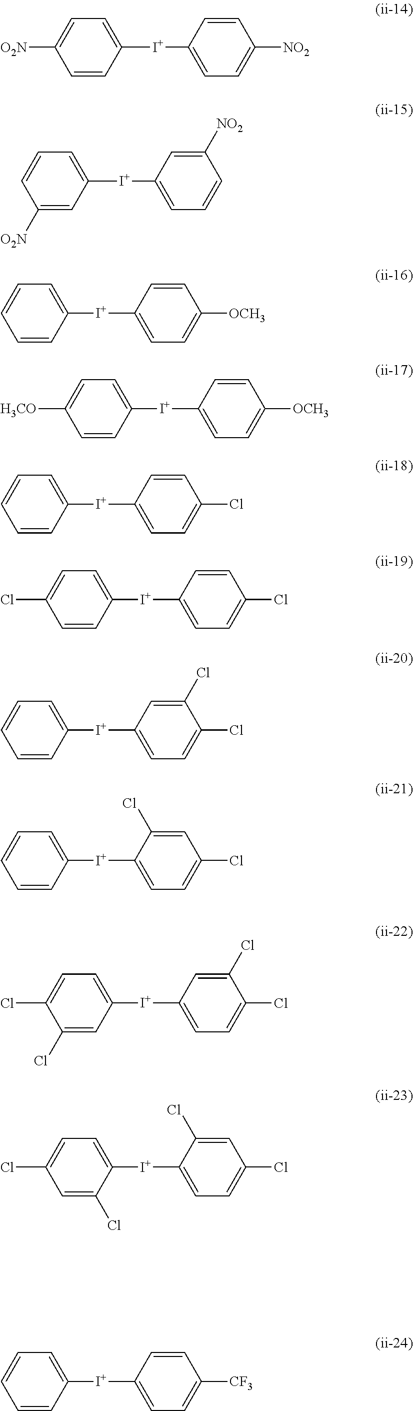

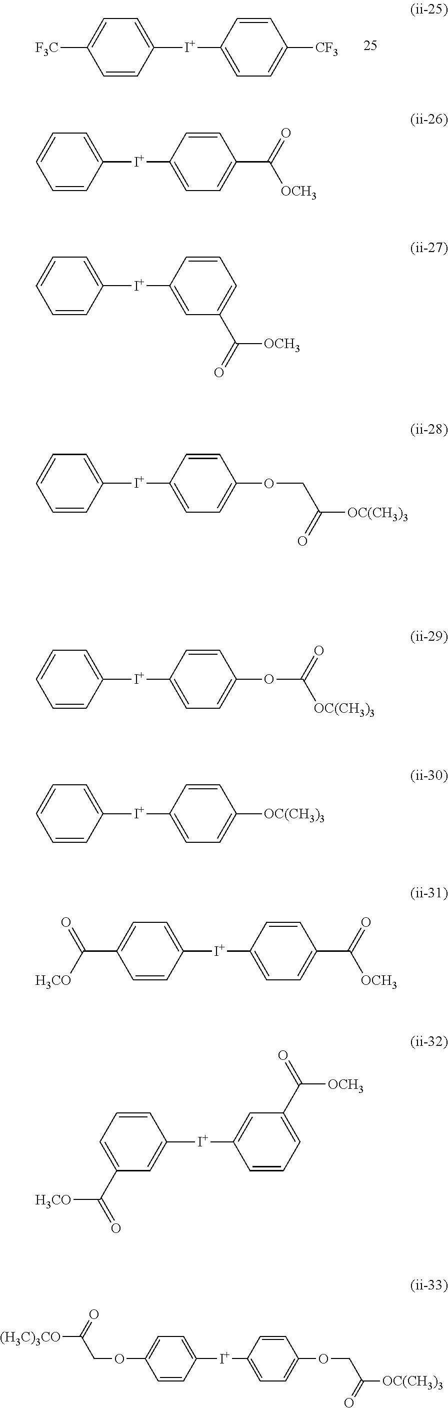

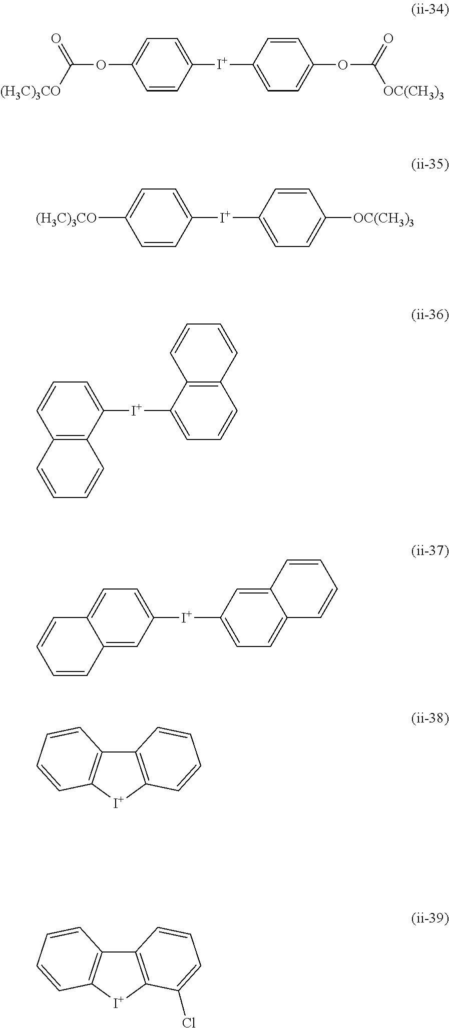

Among these monovalent onium cations, the sulfonium cations shown by the formulas (i-1), (i-2), (i-6), (i-8), (i-13), (i-19), (i-25), (i-27), (i-29), (i-33), (i-51), and (i-54), and the iodonium cations shown by the formulas (ii-1) and (ii-11) are more preferable.

The monovalent onium cation represented by M⁺ in the general formula (1) may be produced by the method described in Advances in Polymer Science, vol. 62, pp. 1-48 (1984), for example.

Examples of a preferable sulfonic acid group-containing compound having a partial structure shown by the general formula (1) include an N-sulfonyloxyimide compound shown by the following general formula (5) (hereinafter may be referred to as “N-sulfonyloxyimide compound (5)”).

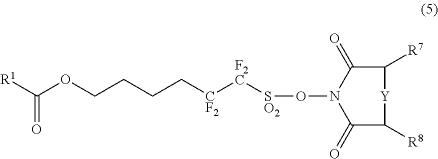

wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms that may include a hetero atom, R⁷ and R⁸ individually represent a hydrogen atom or a substituted or unsubstituted monovalent organic group, or bond to form a ring with the carbon atoms bonded thereto, and Y represents a single bond, a double bond, or a divalent organic group.

Specific examples of the groups represented by R¹ have been described above.

Examples of a preferable imide group bonded to the sulfonyloxy group (SO₂—O—) in the general formula (5) include groups shown by the following formulas (iii-1) to (iii-9).

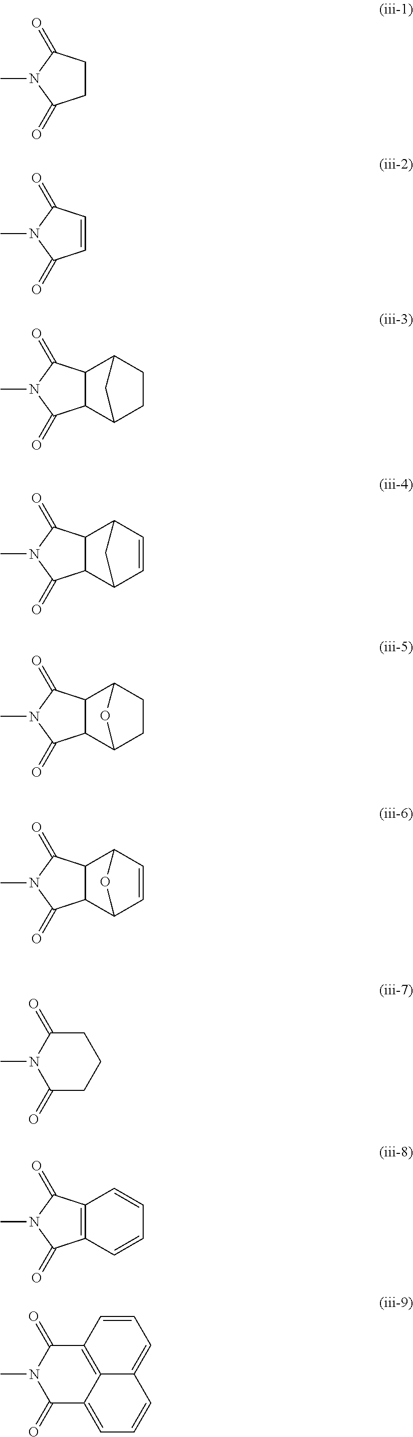

Among these, the groups shown by the formulas (iii-1), (iii-4), (iii-8), and (iii-9) are preferable.

The photoacid generator included in the radiation-sensitive resin composition according to one embodiment of the invention generates an acid due to dissociation of the monovalent onium cation upon exposure or heating. Specifically, the photoacid generator generates a sulfonic acid shown by the following general formula (1a).

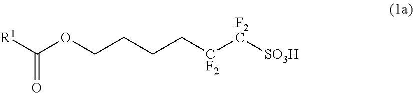

wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms that may include a hetero atom,

Specific examples of the groups represented by R¹ have been described above.

Since the photoacid generator included in the radiation-sensitive resin composition according to one embodiment of the invention has a strong fluorine-containing electron-attracting group at the α-position of the sulfonyl group included in the structure, the sulfonic acid shown by the general formula (1a) generated upon exposure or the like has high acidity. The photoacid generator included in the radiation-sensitive resin composition according to one embodiment of the invention does not easily volatilize during photolithography due to a high boiling point, and exhibits a short (i.e., moderate) acid diffusion length within a resist film. Moreover, since the content of fluorine atoms in the sulfonic acid shown by the general formula (1a) is less than that of a higher perfluoroalkanesulfonic acid, the sulfonic acid exhibits excellent combustibility, and accumulates in a human body to only a small extent.

### Radiation-Sensitive Resin Composition

### <Photoacid Generator (A)>

The radiation-sensitive resin composition according to one embodiment of the present invention includes the photoacid generator (acid generator) that includes a partial structure shown by the general formula (1). The radiation-sensitive resin composition according to one embodiment of the present invention may include only one type of photoacid generator, or may include two or more types of photoacid generator.

The content of the photoacid generator that includes a partial structure shown by the general formula (1) in the radiation-sensitive resin composition according to one embodiment of the present invention differs depending on the type of photoacid generator or the type of additional acid generator, but is normally 0.1 to 25 parts by mass, preferably 0.1 to 20 parts by mass, more preferably 0.1 to 15 parts by mass, and particularly preferably 0.2 to 15 parts by mass, based on 100 parts by mass of an acid-dissociable group-containing resin or an alkali-soluble resin (hereinafter may be referred to as “repeating unit-containing resin” or “resin”). If the content of the photoacid generator is less than 0.1 parts by mass, the desired effects of the embodiment of the invention may not be sufficiently achieved. If the content of the photoacid generator is more than 25 parts by mass, the transparency to radiation, the pattern shape, the heat resistance, and the like may decrease.

The radiation-sensitive resin composition according to one embodiment of the present invention may further include at least one photoacid generator (hereinafter referred to as “additional acid generator”) other than the photoacid generator that includes a partial structure shown by the general formula (1). The additional acid generator is described later in the section entitled “Additional photoacid generator”.

### Acid-Dissociable Group-Containing Resin or Alkali-Soluble Resin

### <Resin (B)>

The acid-dissociable group-containing resin or the alkali-soluble resin preferably includes a repeating unit shown by the following general formula (6) (hereinafter referred to as “repeating unit (6)”) as the acid-dissociable group-containing repeating unit.

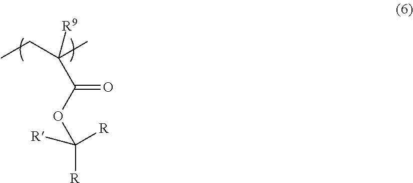

wherein R⁹ represents a hydrogen atom, a methyl group, or a trifluoromethyl group, R′ represents a linear or branched alkyl group having 1 to 4 carbon atoms, and R individually represent a linear or branched alkyl group having 1 to 4 carbon atoms or a monovalent alicyclic hydrocarbon group having 4 to 20 carbon atoms, or bond to form a divalent alicyclic hydrocarbon group having 4 to 20 carbon atoms together with the carbon atom bonded thereto.

Examples of the linear or branched alkyl group having 1 to 4 carbon atoms represented by R′ and R in the general formula (6) include a methyl group, an ethyl group, a propyl group, an isopropyl group, an isobutyl group, and a t-butyl group. Examples of the monovalent alicyclic hydrocarbon group having 4 to 20 carbon atoms represented by R include groups obtained by eliminating one hydrogen atom from a cycloalkane (e.g., cyclobutane, cyclopentane, cyclohexane, cycloheptane, cyclooctane, or cyclodecane) or a bridged alicyclic skeleton (e.g., dicyclopentane, dicyclopentene, tricyclodecane, tetracyclododecane, or adamantane). Examples of the monovalent alicyclic hydrocarbon group having 4 to 20 carbon atoms formed by two R together with the carbon atom bonded thereto include groups obtained by eliminating two hydrogen atoms from the above bridged alicyclic skeleton.

The repeating unit (6) is preferably at least one of a repeating unit shown by the following general formula (6-1), a repeating unit shown by the following general formula (6-2), and a repeating unit shown by the following general formula (6-3), for example.

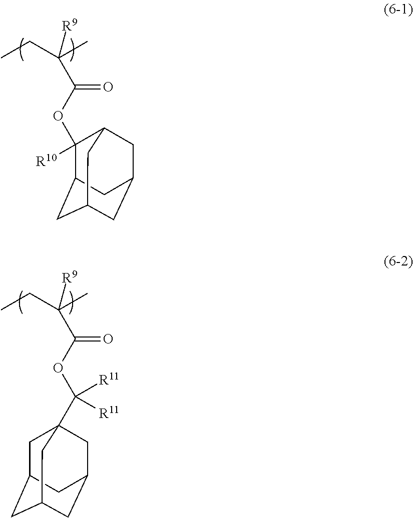

wherein R⁹ represents a hydrogen atom, a methyl group, or a trifluoromethyl group, R¹⁰ represents a linear or branched alkyl group having 1 to 4 carbon atoms, R¹¹ individually represent a linear or branched alkyl group having 1 to 4 carbon atoms, and k is an integer from 0 to 4.

Examples of a preferable monomer that produces the repeating unit (6-1) include 2-methyladamant-2-yl (meth)acrylate, 2-ethyladamant-2-yl (meth)acrylate, 2-n-propyladamant-2-yl (meth)acrylate, 2-isopropyladamant-2-yl (meth)acrylate, and the like.

Examples of a preferable monomer that produces the repeating unit (6-2) include 1-(adamantan-1-yl)-1-methylethyl (meth)acrylate, 1-(adamantan-1-yl)-1-ethylethyl (meth)acrylate, 1-(adamantan-1-yl)-1-methylpropyl (meth)acrylate, 1-(adamantan-1-yl)-1-ethylpropyl (meth)acrylate, and the like.

Examples of a preferable monomer that produces the repeating unit (6-3) include 1-methylcyclopentyl (meth)acrylate, 1-ethylcyclopentyl (meth)acrylate, 1-isopropylcyclopentyl (meth)acrylate, 1-methylcyclohexyl (meth)acrylate, 1-ethylcyclohexyl (meth)acrylate, 1-isopropylcyclohexyl (meth)acrylate, 1-isopropylcycloheptyl (meth)acrylate, 1-ethylcyclooctyl (meth)acrylate, and the like.

The resin (B) includes at least one type of repeating unit (6).

The resin (B) may include at least one repeating unit (hereinafter referred to as “additional repeating unit”) other than the repeating unit (6).

The additional repeating unit is preferably at least one repeating unit selected from the group consisting of repeating units shown by the following general formulas (7-1) to (7-7) (hereinafter referred to as “additional repeating unit (7)”), a repeating unit shown by the following general formula (8) (hereinafter referred to as “additional repeating unit (8)”), a repeating unit shown by the following general formula (9) (hereinafter referred to as “additional repeating unit (9)”), and a repeating unit shown by the following general formula (10) (hereinafter referred to as “additional repeating unit (10)”).

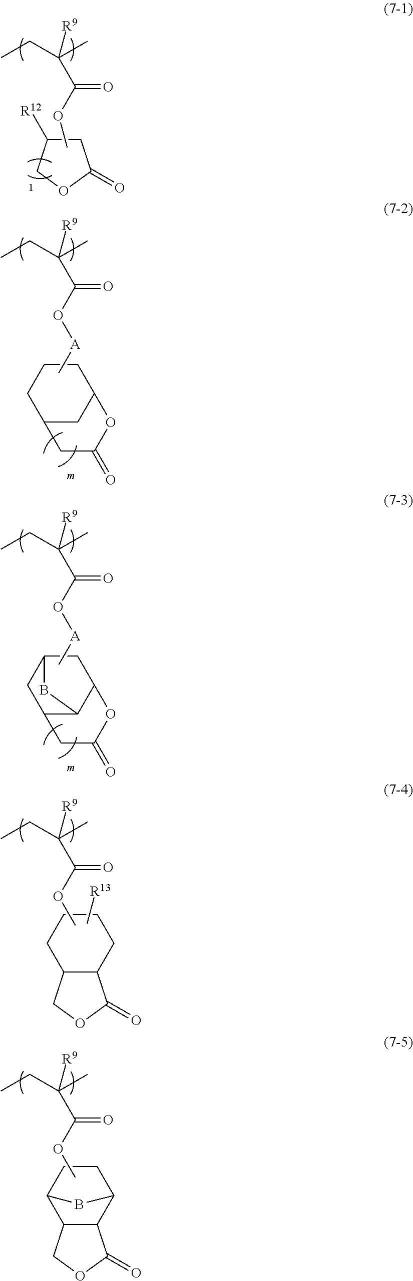

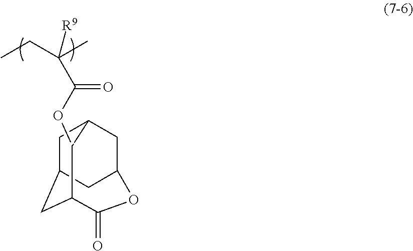

wherein R⁹ represents a hydrogen atom, a methyl group, or a trifluoromethyl group, R¹² represents a hydrogen atom or a substituted or unsubstituted alkyl group having 1 to 4 carbon atoms, R¹³ represents a hydrogen atom or a methoxy group, A represents a single bond or a methylene group, B represents an oxygen atom or a methylene group, 1 is an integer from 1 to 3, and m is 0 or 1.

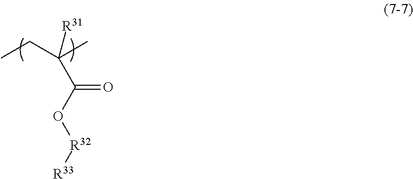

wherein R³¹ represents a hydrogen atom, a fluorine atom, an alkyl group having 1 to 4 carbon atoms, or a fluoroalkyl group having 1 to 4 carbon atoms, R³² represents a single bond or a divalent hydrocarbon group having 1 to 8 carbon atoms, and R³³ represents a monovalent group having a structure shown by the following formula (1),

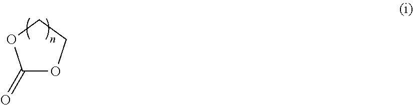

wherein n is 1 or 2.

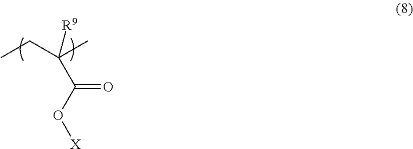

wherein R⁹ represents a hydrogen atom, a methyl group, or a trifluoromethyl group, and X represents a polyalicyclic hydrocarbon group having 7 to 20 carbon atoms that may be substituted with at least one substituent selected from the group consisting of alkyl groups having 1 to 4 carbon atoms, a hydroxyl group, a cyano group, and hydroxyalkyl groups having 1 to 10 carbon atoms.

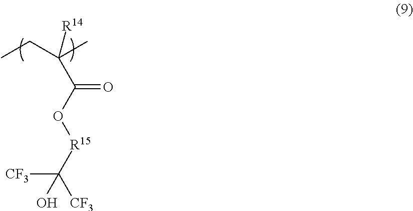

wherein R¹⁴ represents a hydrogen atom, an alkyl group having 1 to 4 carbon atoms, a trifluoromethyl group, or a hydroxymethyl group, and R¹⁵ represents a divalent chain-like or cyclic hydrocarbon group.

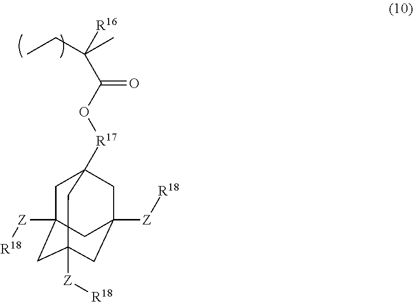

wherein R¹⁶ represents a hydrogen atom or a methyl group, R¹⁷ represents a single bond or a divalent organic group having 1 to 3 carbon atoms, Z individually represent a single bond or a divalent organic group having 1 to 3 carbon atoms, and R¹⁸ individually represent a hydrogen atom, a hydroxyl group, a cyano group, or a COOR¹⁹ group (wherein R¹⁹ represents a hydrogen atom, a linear or branched alkyl group having 1 to 4 carbon atoms, or an alicyclic alkyl group having 3 to 20 carbon atoms), provided that at least one of R¹⁸ preferably does not represent a hydrogen atom, and at least one of Z preferably represents a divalent organic group having 1 to 3 carbon atoms when R¹⁷ represents a single bond.

Examples of a preferable monomer that produces the additional repeating unit (7) include 5-oxo-4-oxatricyclo[4.2.1.0^{3,7}]non-2-yl (meth)acrylate, 9-methoxycarbonyl-5-oxo-4-oxatricyclo[4.2.1.0^{3,7}]non-2-yl (meth)acrylate, 5-oxo-4-oxatricyclo[5.2.1.0^{3,8}]dec-2-yl (meth)acrylate, 10-methoxycarbonyl-5-oxo-4-oxatricyclo[5.2.1.0^{3,8}]non-2-yl (meth)acrylate, 6-oxo-7-oxabicyclo[3.2.1]oct-2-yl (meth)acrylate, 4-methoxycarbonyl-6-oxo-7-oxabicyclo[3.2.1]oct-2-yl (meth)acrylate, 7-oxo-8-oxabicyclo[3.3.1]oct-2-yl (meth)acrylate, 4-methoxycarbonyl-7-oxo-8-oxabicyclo[3.3.1]oct-2-yl (meth)acrylate, 2-oxotetrahydropyran-4-yl (meth)acrylate, 4-methyl-2-oxotetrahydropyran-4-yl (meth)acrylate, 4-ethyl-2-oxotetrahydropyran-4-yl (meth)acrylate, 4-propyl-2-oxotetrahydropyran-4-yl (meth)acrylate, 2-oxotetrahydrofuran-4-yl (meth)acrylate, 5,5-dimethyl-2-oxotetrahydrofuran-4-yl (meth)acrylate, 3,3-dimethyl-2-oxotetrahydrofuran-4-yl (meth)acrylate, 2-oxotetrahydrofuran-3-yl (meth)acrylate, 4,4-dimethyl-2-oxotetrahydrofuran-3-yl (meth)acrylate, 5,5-dimethyl-2-oxotetrahydrofuran-3-yl (meth)acrylate, 5-oxotetrahydrofuran-2-ylmethyl (meth)acrylate, 3,3-dimethyl-5-oxotetrahydrofuran-2-ylmethyl (meth)acrylate, and 4,4-dimethyl-5-oxotetrahydrofuran-2-ylmethyl (meth)acrylate.

R³¹ in the general formula (7-7) represents a hydrogen atom, a fluorine atom, an alkyl group having 1 to 4 carbon atoms (e.g., methyl group, ethyl group, n-propyl group, i-propyl group, n-butyl group, i-butyl group, or t-butyl group), or a fluoroalkyl group having 1 to 4 carbon atoms (e.g., fluoromethyl group, trifluoromethyl group, or pentafluoroethyl group). Among these, a hydrogen atom and a methyl group are particularly preferable. R³² represents a single bond or a divalent hydrocarbon group having 1 to 8 carbon atoms, such as a methylene group, an ethylidene group, an ethylene group, an n-propylene group, an n-butylene group, an n-pentylene group, or an n-octylene group.

Examples of the monovalent group having a structure shown by the formula (i) represented by R³³ include a group having a cyclic ester structure in which n in the formula (i) is 1 or 2, a group having a structure in which some of the carbon atoms of the cyclic ester structure are substituted, a group having a polycyclic structure including the cyclic ester structure, and the like.

Specific examples of the repeating unit (7-7) include repeating units shown by the following formulas (7-7-a) to (7-7-u).

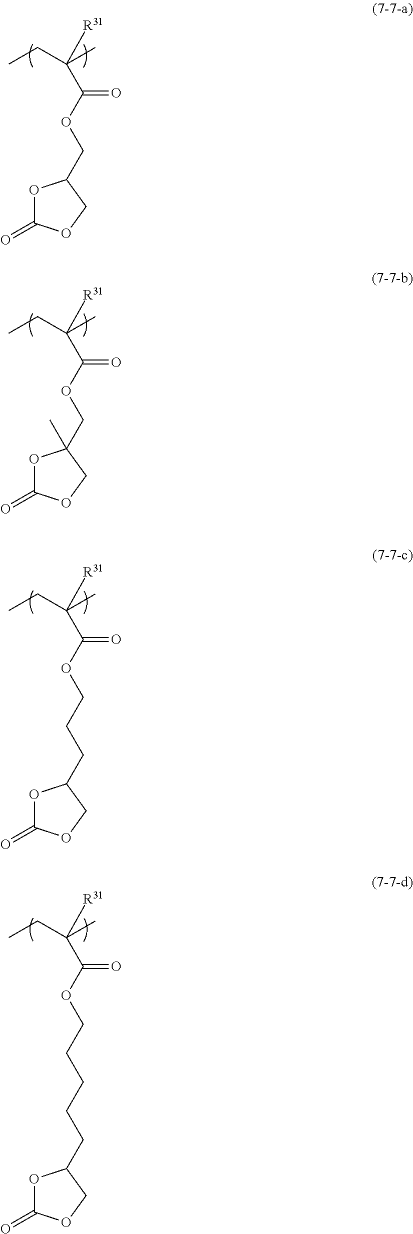

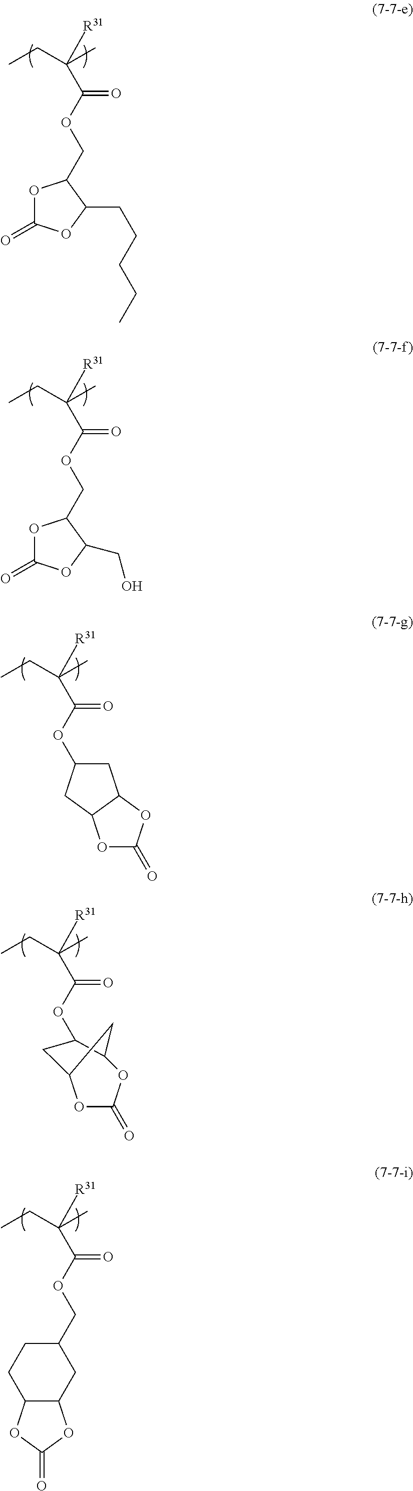

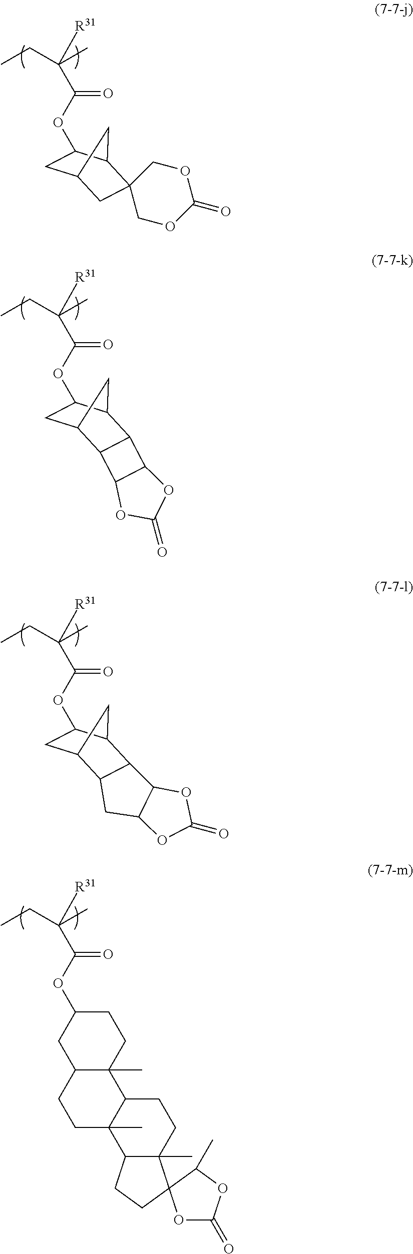

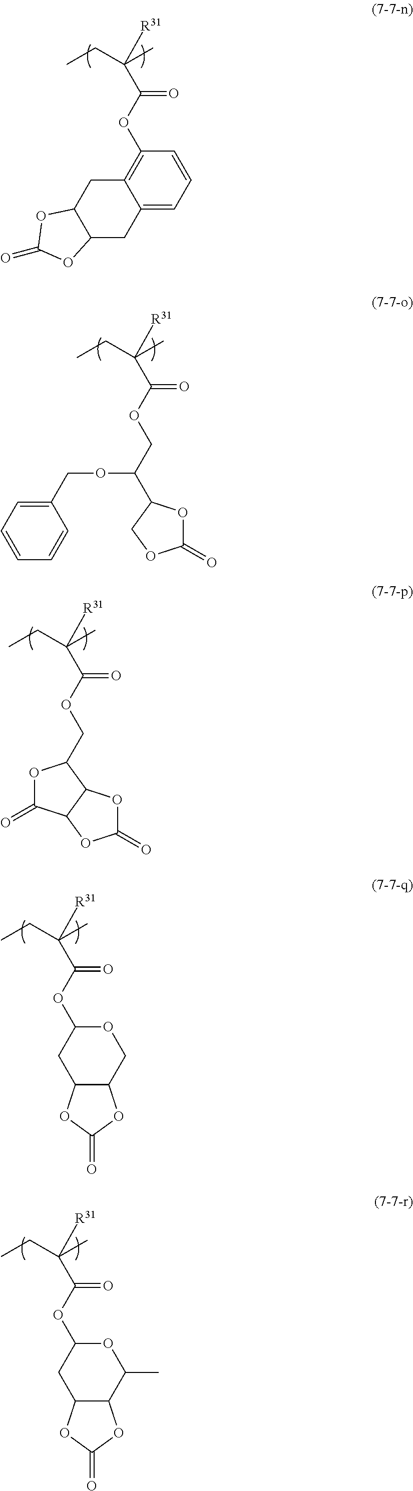

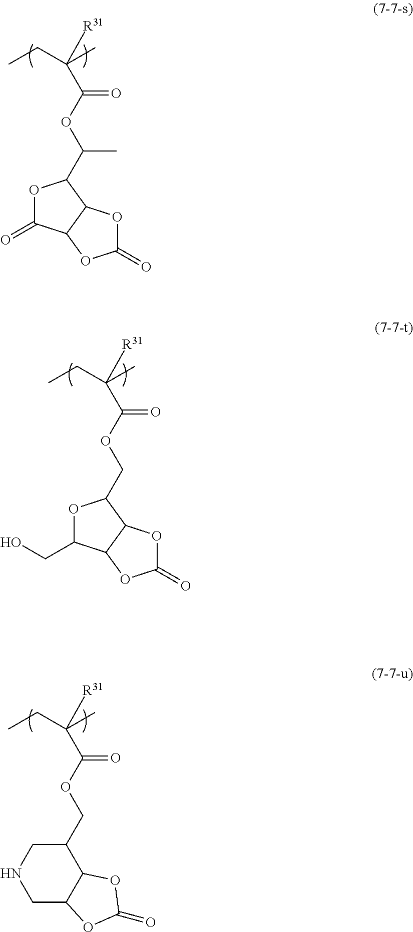

Among these, the repeating unit shown by the formula (7-7-a) is particularly preferably used.

In the additional repeating unit (8) shown by the general formula (8), X preferably represents a polyalicyclic hydrocarbon group having 7 to 20 carbon atoms. Examples of the polyalicyclic hydrocarbon group having 7 to 20 carbon atoms include a hydrocarbon group that includes an alicyclic ring derived from a cycloalkane such as bicyclo[2.2.1]heptane, bicyclo[2.2.2]octane, tricyclo[5.2.1.0^{2,6}]decane, tetracyclo[6.2.1.1^{3,6}.0^{2,7}]dodecane, or tricycle[3.3.1.1^{3,7}]decane.

The alicyclic ring derived from a cycloalkane may be substituted with one or more linear, branched, or cyclic alkyl groups having 1 to 4 carbon atoms (e.g., methyl group, ethyl group, n-propyl group, i-propyl group, n-butyl group, 2-methylpropyl group, 1-methylpropyl group, or t-butyl group). The alicyclic ring need not necessarily be substituted with an alkyl group, but may be substituted a hydroxyl group, a cyano group, a hydroxyalkyl group having 1 to 10 carbon atoms, a carboxyl group, or oxygen. The resin (B) may include one or more types of additional repeating unit (8).

Examples of a preferable monomer that produces the additional repeating unit (8) include bicyclo[2.2.1]heptyl (meth)acrylate, cyclohexyl (meth)acrylate, bicyclo[4.4.0]decanyl (meth)acrylate, bicyclo[2.2.2]octyl (meth)acrylate, tricyclo[5.2.1.0^{2,6}]decanyl (meth)acrylate, tetracyclo[6.2.1.1^{3,6}.0^{2,7}]dodecanyl (meth)acrylate, and tricyclo[3.3.1.1^{3,7}]decanyl (meth)acrylate.

In the additional repeating unit (9) shown by the general formula (9), R¹⁵ preferably represents a chain-like or cyclic divalent hydrocarbon group, and may represent an alkylene glycol group or an alkylene ester group. R¹⁵ preferably represents a saturated linear hydrocarbon group (e.g., methylene group, ethylene group, propylene group (e.g., 1,3-propylene group or 1,2-propylene group), tetramethylene group, pentamethylene group, hexamethylene group, heptamethylene group, octamethylene group, nonamethylene group, decamethylene group, undecamethylene group, dodecamethylene group, tridecamethylene group, tetradecamethylene group, pentadecamethylene group, hexadecamethylene group, heptadecamethylene group, octadecamethylene group, nonadecamethylene group, icosylene group, 1-methyl-1,3-propylene group, 2-methyl-1,3-propylene group, 2-methyl-1,2-propylene group, 1-methyl-1,4-butylene group, 2-methyl-1,4-butylene group, methylidene group, ethylidene group, propylidene group, or 2-propylidene group), a monocyclic hydrocarbon group (e.g., cycloalkylene group having 3 to 10 carbon atoms (e.g., cyclobutylene group (e.g., 1,3-cyclobutylene group), cyclopentylene group (e.g., 1,3-cyclopentylene group), cyclohexylene group (e.g., 1,4-cyclohexylene group), or cyclooctylene group (e.g., a 1,5-cyclooctylene group)), or a bridged cyclic hydrocarbon group (e.g., cyclic hydrocarbon group having 2 to 4 rings and having 4 to 30 carbon atoms (e.g., norbornylene group (e.g., 1,4-norbornylene group or 2,5-norbornylene group) or admantylene group (e.g., 1,5-admantylene group or 2,6-admantylene group).

Examples of a preferable monomer that produces the additional repeating unit (9) include (1,1,1-trifluoro-2-trifluoromethyl-2-hydroxy-3-propyl) (meth)acrylate, (1,1,1-trifluoro-2-trifluoromethyl-2-hydroxy-4-butyl) (meth)acrylate, (1,1,1-trifluoro-2-trifluoromethyl-2-hydroxy-5-pentyl) (meth)acrylate, (1,1,1-trifluoro-2-trifluoromethyl-2-hydroxy-4-pentyl) (meth)acrylate, 2-{[5-(1′,1′,1′-trifluoro-2′-trifluoromethyl-2′-hydroxy)propyl]bicyclo[2.2.1]heptyl} (meth)acrylate, and 4-{[9-(1′,1′,1′-trifluoro-2′-trifluoromethyl-2′-hydroxy)propyl]tetracyclo[6.2.1.1^{3,6}.0^{2,7}]dodec yl} (meth)acrylate.

In the additional repeating unit (10) shown by the formula (10), R¹⁷ represents a single bond or a divalent organic group having 1 to 3 carbon atoms, and Z individually represent a single bond or a divalent organic group having 1 to 3 carbon atoms. Examples of the divalent organic group having 1 to 3 carbon atoms represented by R¹⁷ and Z include a methylene group, an ethylene group, and a propylene group. In the additional repeating unit (10) shown by the formula (10), R¹⁹ in the —COOR¹⁹ group represented by R¹⁸ represents a hydrogen atom, a linear or branched alkyl group having 1 to 4 carbon atoms, or an alicyclic alkyl group having 3 to 20 carbon atoms. Examples of the linear or branched alkyl group having 1 to 4 carbon atoms represented by R¹⁹ include a methyl group, an ethyl group, an n-propyl group, an i-propyl group, an n-butyl group, a 2-methylpropyl group, a 1-methylpropyl group, and a t-butyl group. Examples of the alicyclic alkyl group having 3 to 20 carbon atoms include a cycloalkyl group shown by —CₙH₂ₙ₋₁ (wherein n is an integer from 3 to 20), such as a cyclopropyl group, a cyclobutyl group, a cyclopentyl group, a cyclohexyl group, a cycloheptyl group, and a cyclooctyl group, a polyalicyclic alkyl group such as a bicyclo[2.2.1]heptyl group, a tricyclo[5.2.1.0^{2,6}]decyl group, a tetracyclo[6.2.1.1^{3,6}.0^{2,7}]dodecanyl group, and an adamantyl group, and a group obtained by substituting any of the above cycloalkyl groups or polyalicyclic alkyl groups with one or more linear, branched, or cyclic alkyl groups.

Examples of a preferable monomer that produces the additional repeating unit (10) include 3-hydroxyadamant-1-yl (meth)acrylate, 3,5-dihydroxyadamant-1-yl (meth)acrylate, 3-hydroxyadamant-1-ylmethyl (meth)acrylate, 3,5-dihydroxyadamant-1-ylmethyl (meth)acrylate, 3-hydroxy-5-methyladamant-1-yl (meth)acrylate, 3,5-dihydroxy-7-methyladamant-1-yl (meth)acrylate, 3-hydroxy-5,7-dimethyladamant-1-yl (meth)acrylate, and 3-hydroxy-5,7-dimethyladamant-1-ylmethyl (meth)acrylate.

Examples of a repeating unit (hereinafter may be referred to as “further repeating unit”) other than the repeating units (6) to (10) include units produced by cleavage of a polymerizable unsaturated bond of (meth)acrylates having a bridged hydrocarbon skeleton, such as dicyclopentenyl (meth)acrylate and adamantylmethyl (meth)acrylate; carboxyl group-containing esters having a bridged hydrocarbon skeleton of an unsaturated carboxylic acid, such as carboxynorbornyl (meth)acrylate, carboxytricyclodecanyl (meth)acrylate, and carboxytetracycloundecanyl (meth)acrylate; (meth)acrylates that do not have a bridged hydrocarbon skeleton, such as methyl (meth)acrylate, ethyl (meth)acrylate, n-propyl (meth)acrylate, n-butyl (meth)acrylate, 2-methylpropyl (meth)acrylate, 1-methylpropyl (meth)acrylate, t-butyl (meth)acrylate, 2-hydroxyethyl (meth)acrylate, 2-hydroxypropyl (meth)acrylate, 3-hydroxypropyl (meth)acrylate, cyclopropyl (meth)acrylate, cyclopentyl (meth)acrylate, cyclohexyl (meth)acrylate, 4-methoxycyclohexyl (meth)acrylate, 2-cyclopentyloxycarbonylethyl (meth)acrylate, 2-cyclohexyloxycarbonylethyl (meth)acrylate, and 2-(4-methoxycyclohexyl)oxycarbonylethyl (meth)acrylate; (α-hydroxymethyl)acrylates such as methyl (α-hydroxymethyl)acrylate, ethyl (α-hydroxymethyl)acrylate, n-propyl (α-hydroxymethyl)acrylate, and n-butyl-(α-hydroxymethyl)acrylate; unsaturated nitrile compounds such as (meta)acrylonitrile, α-chloroacrylonitrile, crotonitrile, maleinitrile, fumarnitrile, mesaconitrile, citraconitrile, and itaconitrile; unsaturated amide compounds such as (meth)acrylamide, N,N-dimethyl (meth)acrylamide, crotonamide, maleinamide, fumaramide, mesaconamide, citraconamide, and itaconamide; other nitrogen-containing vinyl compounds such as N-(meth)acryloylmorpholine, N-vinyl-ε-caprolactam, N-vinylpyrrolidone, vinylpyridine, and vinylimidazole; unsaturated carboxylic acids (anhydrides) such as (meth)acrylic acid, crotonic acid, maleic acid, maleic anhydride, fumaric acid, itaconic acid, itaconic anhydride, citraconic acid, citraconic anhydride, and mesaconic acid; carboxyl group-containing esters that do not have a bridged hydrocarbon skeleton of an unsaturated carboxylic acid, such as 2-carboxyethyl (meth)acrylate, 2-carboxypropyl (meth)acrylate, 3-carboxypropyl (meth)acrylate, 4-carboxybutyl (meth)acrylate, and 4-carboxycyclohexyl (meth)acrylate; polyfunctional monomers such as polyfunctional monomers having a bridged hydrocarbon skeleton such as 1,2-adamantanediol di(meth)acrylate, 1,3-adamantanediol di(meth)acrylate, 1,4-adamantanediol di(meth)acrylate, and tricyclodecanyldimethylol di(meth)acrylate; and polyfunctional monomers that do not have a bridged hydrocarbon skeleton, such as methylene glycol di(meth)acrylate, ethylene glycol di(meth)acrylate, propylene glycol di(meth)acrylate, 1,6-hexanediol di(meth)acrylate, 2,5-dimethyl-2,5-hexanediol di(meth)acrylate, 1,8-octanediol di(meth)acrylate, 1,9-nonanediol di(meth)acrylate, 1,4-bis(2-hydroxypropyl)benzene di(meth)acrylate, and 1,3-bis(2-hydroxypropyl)benzene di(meth)acrylate.

The content of the repeating unit (6) in the resin (B) is preferably 10 to 80 mol %, more preferably 15 to 75 mol %, and particularly preferably 20 to 70 mol %, based on the total amount of the repeating units that form the resin (B). If the content of the repeating unit (6) is less than 10 mol %, the solubility of a resist film formed using the radiation-sensitive resin composition according to one embodiment of the invention in an alkaline developer may decrease, so that development defects may occur, or the resolution may decrease. If the content of the repeating unit (6) is more than 80 mol %, the resolution may decrease.

When the resin (B) includes acid-dissociable group-containing repeating units in an amount of 25 to 40 mol %, a resist pattern that has a small MEEF and a small film reduction amount (top loss) can be obtained. The repeating unit (6) is preferable as the acid-dissociable group-containing repeating unit.

The resin (B) may be synthesized by radical polymerization or the like. It is preferable to synthesize the resin (B) by adding a reaction solution including each monomer and a radical initiator dropwise to a solution including a reaction solvent or a monomer, and polymerizing the monomers, or adding a reaction solution including each monomer and a reaction solution including a radical initiator dropwise to a solution including a reaction solvent or a monomer, and polymerizing the monomers, or adding reaction solutions including respective monomers and a reaction solution including a radical initiator dropwise to a solution including a reaction solvent or a monomer, and polymerizing the monomers, for example.

The reaction temperature may be appropriately set depending on the type of initiator, but is normally 30 to 180° C. The reaction temperature is preferably 40 to 160° C., and more preferably 50 to 140° C. The addition time may be appropriately set depending on the reaction temperature, the type of initiator, and the type of monomer, but is normally 30 minutes to 8 hours. The addition time is preferably 45 minutes to 6 hours, and more preferably 1 to 5 hours. The total reaction time including the addition time may be appropriately set, but is normally 30 minutes to 8 hours. The total reaction time is preferably 45 minutes to 7 hours, and more preferably 1 to 6 hours. When adding a monomer solution dropwise to another monomer solution, the content of monomers in the monomer solution added to the other monomer solution is preferably 30 mol % or more, more preferably 50 mol % or more, and still preferably 70 mol % or more, based on the total amount of monomers used for polymerization.

Examples of the radical initiator used for polymerization include 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis-iso-butylonitrile, 2,2′-azobis(2-methylbutyronitrile), 1,1′-azobis(cyclohexane-1-carbonitrile), 2,2′-azobis(2-methyl-N-phenylpropioneamidine)dihydrochloride, 2,2′-azobis(2-methyl-N-2-propenylpropioneamidine)dihydrochloride, 2,2′-azobis[2-(5-methyl-2-imidazolin-2-yl)propane]dihydrochloride, 2,2′-azobis{2-methyl-N-[1,1-bis(hydroxymethyl)-2-hydroxyethyl]propioneamide}, dimethyl-2,2′-azobis(2-methylpropionate), 4,4′-azobis(4-cyanovaleric acid), 2,2′-azobis(2-(hydroxymethyl)propionitrile), and the like. These radical initiators may be used either individually or in combination.

A solvent that dissolves the monomers and does not hinder polymerization (e.g., a polymerization inhibitor such as nitrobenzene or a chain transfer agent such as a mercapto compound) may be used as the polymerization solvent. Examples of such a solvent include alcohols, ethers, ketones, amides, esters, lactones, nitriles, and a mixture thereof. Examples of alcohols include methanol, ethanol, propanol, isopropanol, butanol, ethylene glycol, propylene glycol, ethylene glycol monomethyl ether, ethylene glycol monoethyl ether, and 1-methoxy-2-propanol. Examples of ethers include propyl ether, isopropyl ether, butyl methyl ether, tetrahydrofuran, 1,4-dioxane, 1,3-dioxolane, and 1,3-dioxane. Examples of ketones include acetone, methyl ethyl ketone, diethyl ketone, methyl isopropyl ketone, and methyl isobutyl ketone. Examples of amides include N,N-dimethylformamide and N,N-dimethylacetamide. Examples of esters and lactones include ethyl acetate, methyl acetate, isobutyl acetate, and γ-butyrolactone. Examples of nitriles include acetonitrile, propionitrile, and butyronitrile. These solvents may be used either individually or in combination.

After polymerization, the resulting resin is preferably collected by re-precipitation. Specifically, the reaction solution is poured into a re-precipitation solvent after polymerization to collect the target resin as a powder. Examples of the re-precipitation solvent include water, alcohols, ethers, ketones, amides, esters, lactones, nitriles, and a mixture thereof. Examples of alcohols include methanol, ethanol, propanol, isopropanol, butanol, ethylene glycol, propylene glycol, and 1-methoxy-2-propanol. Examples of ethers include propyl ether, isopropyl ether, butyl methyl ether, tetrahydrofuran, 1,4-dioxane, 1,3-dioxolane, and 1,3-dioxane. Examples of ketones include acetone, methyl ethyl ketone, diethyl ketone, methyl isopropyl ketone, and methyl isobutyl ketone. Examples of amides include N,N-dimethylformamide and N,N-dimethylacetamide. Examples of esters and lactones include ethyl acetate, methyl acetate, isobutyl acetate, and γ-butyrolactone. Examples of nitriles include acetonitrile, propionitrile, and butyronitrile.

The weight average molecular weight (Mw) of the resin included in the radiation-sensitive resin composition according to one embodiment of the invention determined by gel permeation chromatography is preferably 1000 to 100,000, more preferably 1500 to 80,000, and particularly preferably 2000 to 50,000. If the Mw of the resin is less than 1000, the heat resistance of the resulting resist may deteriorate. If the Mw of the resin is more than 100,000, the developability of the resulting resist may deteriorate. The ratio (Mw/Mn) of the Mw to the number average molecular weight (Mn) is preferably 1 to 5, and more preferably 1 to 3.

It is preferable that the impurity (e.g., halogen or metal) content in the polymerization solution be as low as possible. If the polymerization solution has a low impurity content, the sensitivity, the resolution, the process stability, the pattern shape, and the like of the resulting resist are further improved. The resin may be purified by chemical purification (e.g., washing with water or liquid-liquid extraction), a combination of chemical purification and physical purification (e.g., ultrafiltration or centrifugation), or the like. The above resins may be used either individually or in combination.

### <Solvent (D)>

Examples of the solvent included in the radiation-sensitive resin composition according to one embodiment of the invention include ethylene glycol monoalkyl ether acetates such as ethylene glycol monomethyl ether acetate, ethylene glycol monoethyl ether acetate, ethylene glycol mono-n-propyl ether acetate, and ethylene glycol mono-n-butyl ether acetate;

propylene glycol monoalkyl ethers such as propylene glycol methyl ether, propylene glycol monoethyl ether, propylene glycol mono-n-propyl ether, and propylene glycol mono-n-butyl ether; propylene glycol dialkyl ethers such as propylene glycol dimethyl ether, propylene glycol diethyl ether, propylene glycol di-n-propyl ether, and propylene glycol di-n-butyl ether; propylene glycol monoalkyl ether acetates such as propylene glycol monomethyl ether acetate, propylene glycol monoethyl ether acetate, propylene glycol mono-n-propyl ether acetate, and propylene glycol mono-n-butyl ether acetate;
lactates such as methyl lactate, ethyl lactate, n-propyl lactate, and i-propyl lactate; formates such as n-amyl formate and i-amyl formate; acetates such as ethyl acetate, n-propyl acetate, i-propyl acetate, n-butyl acetate, i-butyl acetate, n-amyl acetate, i-amyl acetate, 3-methoxybutyl acetate, and 3-methyl-3-methoxybutyl acetate; propionates such as i-propyl propionate, n-butyl propionate, i-butyl propionate, and 3-methyl-3-methoxybutyl propionate;
other esters such as ethyl hydroxyacetate, ethyl 2-hydroxy-2-methylpropionate, methyl 2-hydroxy-3-methylbutyrate, ethyl methoxyacetate, ethyl ethoxyacetate, methyl 3-methoxypropionate, ethyl 3-methoxypropionate, methyl 3-ethoxypropionate, ethyl 3-ethoxypropionate, 3-methyl-3-methoxybutyl butyrate, methyl acetoacetoate, ethyl acetoacetate, methyl pyruvate, and ethyl pyruvate; aromatic hydrocarbons such as toluene and xylene;
ketones such as methyl ethyl ketone, 2-pentanone, 2-hexanone, 2-heptanone, 3-heptanone, 4-heptanone, and cyclohexanone; amides such as N-methylformamide, N,N-dimethylformamide, N-methylacetamide, N,N-dimethylacetamide, and N-methylpyrrolidone; lactones such as γ-butyrolactone; and the like. These solvents may be used either individually or in combination.

### <Additional Photoacid Generator>

The radiation-sensitive resin composition according to one embodiment of the invention may include a photoacid generator (hereinafter may be referred to as “additional acid generator”) other than the acid generator that includes a partial structure shown by the general formula (1). Examples of the additional acid generator include onium salt compounds, sulfonic acid compounds, and the like.

Examples of the onium salt compounds include iodonium salts, sulfonium salts, phosphonium salts, diazonium salts, pyridinium salts, and the like.

Specific examples of the onium salt compounds include diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, cyclohexyl•2-oxocyclohexyl•methylsulfonium trifluoromethanesulfonate, dicyclohexyl•2-oxocyclohexylsulfonium trifluoromethanesulfonate, 2-oxocyclohexyldimethylsulfonium trifluoromethanesulfonate, bis(4-t-butylphenyl)iodonium nonafluorobutanesulfonate, bis(4-t-butylphenyl)iodonium trifluorobutanesulfonate, bis(4-t-butylphenyl)iodonium perfluorooctanesulfonate, bis(4-t-butylphenyl)iodonium p-toluenesulfonate, bis(4-t-butylphenyl)iodonium 10-camphorsulfonate, 4-trifluoromethyl benzenesulfonate, bis(4-t-butylphenyl)iodonium perfluorobenzenesulfonate, diphenyliodonium p-toluenesulfonate, diphenyliodonium benzenesulfonate, diphenyliodonium 10-camphorsulfonate, diphenyliodonium 4-trifluoromethylbenzenesulfonate, diphenyliodonium perfluorobenzenesulfonate, bis(p-fluorophenyl)iodonium trifluoromethanesulfonate, bis(p-fluorophenyl)iodonium nonafluoromethanesulfonate, bis(p-fluorophenyl)iodonium 10-camphorsulfonate, (p-fluorophenyl)(phenyl)iodonium trifluoromethanesulfonate, triphenylsulfonium nonafluorobutanesulfonate, triphenylsulfonium trifluoromethanesulfonate, triphenylsulfonium perfluorooctanesulfonate, triphenylsulfonium-2-bicyclo[2.2.1]hept-2-yl-1,1-difluoroethanesulfonate, triphenylsulfonium-2-bicyclo[2.2.1]hept-2-yl-1,1,2,2-tetrafluoroethanesulfonate, triphenylsulfonium p-toluenesulfonate, triphenylsulfonium benzenesulfonate, triphenylsulfonium 10-camphorsulfonate, triphenylsulfonium 4-trifluoromethylbenzenesulfonate, triphenylsulfonium perfluorobenzenesulfonate, 4-hydroxyphenyldiphenylsulfonium trifluoromethanesulfonate, tris(p-methoxyphenyl)sulfonium nonafluorobutanesulfonate, tris(p-methoxyphenyl)sulfonium trifluoromethanesulfonate, tris(p-methoxyphenyl)sulfonium perfluorooctanesulfonate, tris(p-methoxyphenyl)sulfonium p-toluenesulfonate, tris(p-methoxyphenyl)sulfonium benzenesulfonate, tris(p-methoxyphenyl)sulfonium 10-camphorsulfonate, tris(p-fluorophenyl)sulfonium trifluoromethanesulfonate, tris(p-fluorophenyl)sulfonium p-toluenesulfonate, (p-fluorophenyl)diphenylsulfonium trifluoromethanesulfonate, 4-butoxy-1-naphthyltetrahydrothiophenium nonafluorobutanesulfonate, and 4-butoxy-1-naphthyltetrahydrothiophenium-2-bicyclo[2.2.1]hept-2-yl-1,1,2,2-tetrafluoroethanesulfonate.

Examples of the sulfonic acid compounds include alkyl sulfonates, alkylsulfonic acid imides, haloalkyl sulfonates, aryl sulfonates, and imino sulfonates.

Specific examples of the sulfonic acid compounds include benzoin tosylate, tris(trifluoromethanesulfonate) of pyrogallol, nitrobenzyl-9,10-diethoxyanthracene-2-sulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, N-hydroxysuccinimide trifluoromethanesulfonate, N-hydroxysuccinimide nonafluoro-n-butanesulfonate, N-hydroxysuccinimide perfluoro-n-octanesulfonate, 1,8-naphthalenedicarboxylic acid imide trifluoromethanesulfonate, 1,8-naphthalenedicarboxylic acid imide nonafluoro-n-butanesulfonate, and 1,8-naphthalenedicarboxylic acid imide perfluoro-n-octanesulfonate.

Among these additional acid generators, diphenyliodonium trifluoromethanesulfonate, diphenyliodonium nonafluoro-n-butanesulfonate, diphenyliodonium perfluoro-n-octanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, cyclohexyl•2-oxocyclohexylmethylsulfonium trifluoromethanesulfonate, dicyclohexyl•2-oxocyclohexylsulfonium trifluoromethanesulfonate, 2-oxocyclohexyldimethylsulfonium trifluoromethanesulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, N-hydroxysuccinimide trifluoromethanesulfonate, N-hydroxysuccinimide nonafluoro-n-butanesulfonate, N-hydroxysuccinimideperfluoro-n-octanesulfonate, 1,8-naphthalenedicarboxylic acid imide trifluoromethanesulfonate, triphenylsulfonium nonafluorobutanesulfonate, triphenylsulfonium trifluoromethanesulfonate, triphenylsulfonium-2-bicyclo[2.2.1]hept-2-yl-1,1-difluoroethanesulfonate, triphenylsulfonium-2-bicyclo[2.2.1]hept-2-yl-1,1,2,2-tetrafluoroethanesulfonate, 4-butoxy-1-naphthyltetrahydrothiophenium nonafluorobutanesulfonate, and 4-butoxy-1-naphthyltetrahydrothiophenium-2-bicyclo[2.2.1]hept-2-yl-1,1,2,2-tetrafluoroethanesulfonate are preferable. These additional acid generators may be used either individually or in combination.

When the radiation-sensitive resin composition according to one embodiment of the invention includes the additional acid generator, the content of the additional acid generator is preferably 0.5 to 30 parts by mass, and more preferably 1 to 25 parts by mass, based on 100 parts by mass of the photoacid generator that includes a partial structure shown by the general formula (1), so that the resist film formed using the radiation-sensitive resin composition according to one embodiment of the invention exhibits excellent sensitivity and developability. If the content of the additional acid generator is less than 0.5 parts by mass, the resolution of the resulting resist film may decrease. If the content of the additional acid generator is more than 30 parts by mass, a rectangular resist pattern may not be obtained due to a decrease in transparency to radiation.

### <Additives>

The radiation-sensitive resin composition according to one embodiment of the invention may optionally include additives such as an acid diffusion controller (C), an alicyclic additive that includes an acid-dissociable group, a surfactant, a photosensitizer, an alkali-soluble resin, a low-molecular-weight alkali solubility controller that includes an acid-dissociable protecting group, a halation inhibitor, a preservation stabilizer, and an antifoaming agent.

The acid diffusion controller (C) controls diffusion of an acid generated by the acid generator upon exposure within the resist film to suppress undesired chemical reactions in the unexposed area. The acid diffusion controller (C) improves the storage stability of the resulting radiation-sensitive resin composition, improves the resolution of the resulting resist, and suppresses a change in resist pattern line width due to a change in post-exposure delay (PED) from exposure to post-exposure bake. This makes it possible to obtain a composition that exhibits excellent process stability.

The acid diffusion controller (C) is preferably an acid diffusion controller (a) shown by the following general formula (11).

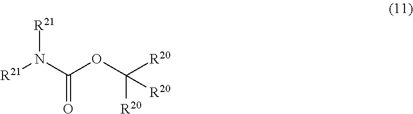

wherein R²⁰ and R²¹ individually represent a hydrogen atom, a substituted or unsubstituted linear, branched, or cyclic alkyl group having 1 to 20 carbon atoms, an aryl group, or an aralkyl group, provided that R²⁰ or R²¹ may bond to form a saturated or unsaturated divalent hydrocarbon group having 4 to 20 carbon atoms, or a derivative thereof, together with the carbon atom bonded thereto.

Examples of the acid diffusion controller (a) shown by the general formula (11) include N-t-butoxycarbonyl group-containing amino compounds such as N-t-butoxycarbonyldi-n-octylamine, N-t-butoxycarbonyldi-n-nonylamine, N-t-butoxycarbonyldi-n-decylamine, N-t-butoxycarbonyldicyclohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidine methanol, (R)-(+)-1-(t-butoxycarbonyl)-2-pyrrolidinemethanol, N-t-butoxycarbonyl-4-hydroxypiperidine, N-t-butoxycarbonylpyrrolidine, N,N′-di-t-butoxycarbonylpiperazine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, and N-t-butoxycarbonyl-2-phenylbenzimidazole.

A compound that loses acid-diffusion controllability upon decomposition due to exposure (hereinafter may be referred to as “acid diffusion controller (b)”) may also be preferably used as the acid diffusion controller (C).

Examples of the acid diffusion controller (b) include a compound shown by the following general formula (12).

X⁺Z⁻ (12)

wherein X⁺ represents a cation shown by the following general formula (12-1) or (12-2), and Z⁻ represents an anion shown by OH⁻, R²²—COO⁻, or R²²—SO₃⁻ (wherein R²² represents a substituted or unsubstituted alkyl group or a substituted or unsubstituted aryl group).

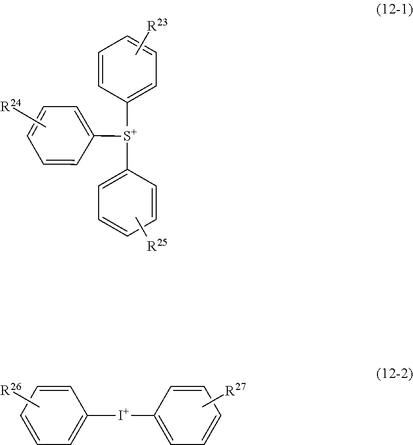

wherein R²³ to R²⁵ individually represent a hydrogen atom, an alkyl group, an alkoxy group, a hydroxyl group, or a halogen atom, and R²⁶ and R²⁷ individually represent a hydrogen atom, an alkyl group, an alkoxy group, a hydroxyl group, or a halogen atom.

X⁺ in the general formula (12) represents a cation shown by the general formula (12-1) or (12-2). R²³ to R²⁵ in the general formula (12-1) individually represent a hydrogen atom, an alkyl group, an alkoxy group, a hydroxyl group, or a halogen atom. R²³ to R²⁵ preferably represent a hydrogen atom, an alkyl group, an alkoxy group, or a halogen atom. R²⁶ and R²⁷ in the general formula (12-2) individually represent a hydrogen atom, an alkyl group, an alkoxy group, a hydroxyl group, or a halogen atom. R²⁶ and R²⁷ preferably represent a hydrogen atom, an alkyl group, or a halogen atom.

Z⁻ in the general formula (12) represents an anion shown by OH⁻, R²²—COO⁻, or R²²—SO₃⁻. R²² represents a substituted or unsubstituted alkyl group or a substituted or unsubstituted aryl group. R²² preferably represents an aryl group since the solubility of the composition in a developer decreases.

Examples of the substituted or unsubstituted alkyl group include groups including one or more substituents, such as a hydroxyalkyl group having 1 to 4 carbon atoms (e.g., hydroxymethyl group, 1-hydroxyethyl group, 2-hydroxyethyl group, 1-hydroxypropyl group, 2-hydroxypropyl group, 3-hydroxypropyl group, 1-hydroxybutyl group, 2-hydroxybutyl group, 3-hydroxybutyl group, and 4-hydroxybutyl group); an alkoxyl group having 1 to 4 carbon atoms (e.g., methoxy group, ethoxy group, n-propoxy group, i-propoxy group, n-butoxy group, 2-methylpropoxy group, 1-methylpropoxy group, and t-butoxy group); a cyano group; and a cyanoalkyl group having 2 to 5 carbon atoms (e.g., cyanomethyl group, 2-cyanoethyl group, 3-cyanopropyl group, and 4-cyanobutyl group). Among these, a hydroxymethyl group, a cyano group, and a cyanomethyl group are preferable.

Examples of the substituted or unsubstituted aryl group include a phenyl group, a benzyl group, a phenylethyl group, a phenylpropyl group, a phenylcyclohexyl group, and groups obtained by substituting these groups with a hydroxyl group, a cyano group, or the like. Among these, a phenyl group, a benzyl group, and a phenylcyclohexyl group are preferable.

Specific examples of the acid diffusion controller (b) include sulfonium salt compounds such as triphenylsulfonium hydroxide, triphenylsulfonium acetate, triphenylsulfonium salicylate, diphenyl-4-hydroxyphenylsulfonium hydroxide, diphenyl-4-hydroxyphenylsulfonium acetate, diphenyl-4-hydroxyphenylsulfonium salicylate, triphenylsulfonium 1-adamantanecarboxylate, triphenylsulfonium 10-camphorsulfonate, and 4-t-butoxyphenyldiphenylsulfonium 10-camphorsulfonate; and iodonium salt compounds such as bis(4-t-butylphenyl)iodonium hydroxide, bis(4-t-butylphenyl)iodonium acetate, bis(4-t-butylphenyl)iodonium hydroxide, bis(4-t-butylphenyl)iodonium acetate, bis(4-t-butylphenyl)iodonium salicylate, 4-t-butylphenyl-4-hydroxyphenyliodonium hydroxide, 4-t-butylphenyl-4-hydroxyphenyliodonium acetate, 4-t-butylphenyl-4-hydroxyphenyliodonium salicylate, bis(4-t-butylphenyl)iodonium 1-adamantanecarboxylate, bis(4-t-butylphenyl)iodonium 10-camphorsulfonate, and diphenyliodonium 10-camphorsulfonate. These acid diffusion controllers (b) may be used either individually or in combination.

Examples of the acid diffusion controller (C) other than the acid diffusion controllers (a) and (b) include tertiary amine compounds, quaternary ammonium hydroxide compounds, and other nitrogen-containing heterocyclic compounds.

Examples of the tertiary amine compounds include tri(cyclo)alkylamines such as triethylamine, tri-n-propylamine, tri-n-butylamine, tri-n-pentylamine, tri-n-hexylamine, tri-n-heptylamine, tri-n-octylamine, cyclohexyl dimethylamine, dicyclohexyl methylamine, and tricyclohexylamine; aromatic amines such as aniline, N-methylaniline, N,N-dimethylaniline, 2-methylaniline, 3-methylaniline, 4-methylaniline, 4-nitroaniline, 2,6-dimethylaniline, and 2,6-diisopropylaniline; alkanolamines such as triethanolamine and N,N-di(hydroxyethyl)aniline; N,N,N′,N′-tetramethylethylenediamine, N,N,N′,N′-tetrakis(2-hydroxypropyl)ethylenediamine, 1,3-bis[1-(4-aminophenyl)-1-methylethyl]benzenetetramethylenediamine, bis(2-dimethylaminoethyl)ether, and bis(2-diethylaminoethyl)ether.

Examples of the quaternary ammonium hydroxide compounds include tetra-n-propylammonium hydroxide and tetra-n-butylammonium hydroxide.

Examples of the nitrogen-containing heterocyclic compounds include pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinamide, quinoline, 4-hydroxyquinoline, 8-oxyquinoline, and acridine; piperazines such as piperazine, 1-(2-hydroxyethyl)piperazine; pyrazine, pyrazole, pyridazine, quinoxaline, purine, pyrrolidine, piperidine, 3-piperidino-1,2-propanediol, morpholine, 4-methylmorpholine, 1,4-dimethylpiperazine, 1,4-diazabicyclo[2.2.2]octane, imidazole, 4-methylimidazole, 1-benzyl-2-methylimidazole, 4-methyl-2-phenylimidazole, benzimidazole, and 2-phenylbenzimidazole.

These acid diffusion controllers (C) including the acid diffusion controller (a) may be used either individually or in combination.

The acid diffusion controller (C) is preferably used in a total amount of less than 10 parts by mass, and more preferably less than 5 parts by mass, based on 100 parts by mass of the resin (A), in order to provide the resulting resist with high sensitivity. If the total amount of the acid diffusion controller (C) is more than 10 parts by mass, the sensitivity of the resist may decrease to a large extent. If the total amount of the acid diffusion controller (C) is less than 0.001 parts by mass, the pattern shape and the dimensional accuracy of the resulting resist may deteriorate depending on the process conditions.

The alicyclic additive that includes an acid-dissociable group further improve the dry etching resistance, the pattern shape, adhesion to a substrate, and the like. Examples of the alicyclic additive include adamantane derivatives such as t-butyl 1-adamantanecarboxylate, t-butoxycarbonylmethyl 1-adamantanecarboxylate, di-t-butyl 1,3-adamantanedicarboxylate, t-butyl 1-adamantaneacetate, t-butoxycarbonylmethyl 1-adamantaneacetate, and di-t-butyl 1,3-adamantanediacetate; deoxycholates such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; and lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate. These alicyclic additives may be used either individually or in combination.

The surfactant improves the applicability, striation, developability, and the like of the radiation-sensitive resin composition. Examples of the surfactant include nonionic surfactants such as polyoxyethylene lauryl ether, polyoxyethylene stearyl ether, polyoxyethylene oleyl ether, polyoxyethylene n-octyl phenyl ether, polyoxyethylene n-nonyl phenyl ether, polyethylene glycol dilaurate, and polyethylene glycol distearate. Examples of commercially available products of the surfactant include KP341 (manufactured by Shin-Etsu Chemical Co., Ltd.), Polyflow No. 75, Polyflow No. 95 (manufactured by Kyoeisha Chemical Co., Ltd.), EFTOP EF301, EFTOP EF303, EFTOP EF352 (manufactured by JEMCO, Inc.), Megafac F171, Megafac F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.), and the like. These surfactants may be used either individually or in combination.

### <Formation of Photoresist Pattern>

The radiation-sensitive resin composition according to one embodiment of the invention is useful as a chemically-amplified resist. When forming a resist film using the radiation-sensitive resin composition according to one embodiment of the invention, the acid-dissociable group included in the resin dissociates due to an acid generated by the acid generator that includes a partial structure shown by the general formula (1) (and optionally an acid generated by the additional acid generator) upon exposure, so that a carboxyl group is produced. As a result, the solubility of the exposed area of the resist in an alkaline developer increases, so that the exposed area is dissolved (removed) in an alkaline developer to obtain a positive-tone resist pattern.

When forming a resist pattern using the radiation-sensitive resin composition according to one embodiment of the invention, the acid generator, the additional acid generator (optional), and the resin that includes the above repeating units are homogenously dissolved in the solvent to obtain a preliminary composition. The preliminary composition is filtered through a filter having a pore size of about 200 nm to obtain a composition solution. The solvent is preferably used so that the composition has a total solid content of 0.1 to 50 mass %, and more preferably 1 to 40 mass %. This ensures a smooth filtration operation.

The composition solution is then applied to a substrate (e.g., silicon wafer or aluminum-coated wafer) using an appropriate application method (e.g., rotational coating, cast coating, or roll coating) to form a resist film. After performing an optional heat treatment (hereinafter referred to as “soft bake (SB)”), the resist film is exposed so that a given resist pattern is formed. Radiation used for exposure is appropriately selected from visible rays, ultraviolet rays, deep ultraviolet rays, X-rays, electron beams, and the like. It is preferable to use deep ultraviolet rays such as ArF excimer laser light (wavelength: 193 nm) or KrF excimer laser light (wavelength: 248 nm). It is particularly preferable to use ArF excimer laser light (wavelength: 193 nm). It is preferable to perform post-exposure bake (“PEB”). The acid-dissociable group included in the resin smoothly dissociates by performing PEB. The PEB temperature differs depending on the composition of the radiation-sensitive resin composition, but is preferably 30 to 200° C., and more preferably 50 to 170° C.

In order to bring out the potential of the radiation-sensitive resin composition to a maximum extent, an organic or inorganic antireflective film may be formed on the substrate, as disclosed in Japanese Examined Patent Publication (KOKOKU) No. 6-12452, for example. A protective film may be formed on the resist film so that the resist film is not affected by basic impurities and the like contained in the environmental atmosphere, as disclosed in Japanese Patent Application Publication (KOKAI) No. 5-188598, for example. These methods may be used in combination.

The resist film thus exposed is developed to form a given resist pattern. As the developer used for development, it is preferable to use an alkaline aqueous solution prepared by dissolving at least one alkaline compound (e.g., sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, or 1,5-diazabicyclo-[4.3.0]-5-nonene) in water. The concentration of the aqueous alkaline solution is preferably 10 mass % or less. If the concentration of the aqueous alkaline solution is more than 10 mass %, the unexposed area may also be dissolved in the developer.

An organic solvent may be added to the developer, for example. Examples of the organic solvent include ketones such as acetone, methyl ethyl ketone, methyl i-butyl ketone, cyclopentanone, cyclohexanone, 3-methylcyclopentanone, and 2,6-dimethylcyclohexanone; alcohols such as methyl alcohol, ethyl alcohol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol; acetonylacetone; and dimethylformamide.

These organic solvents may be used either individually or in combination. The organic solvent is preferably used in an amount of 100 vol % or less based on the amount of the alkaline aqueous solution. If the amount of the organic solvent is more than 100 vol %, the exposed area may remain undeveloped due to a decrease in developability. An appropriate amount of a surfactant or the like may also be added to the developer. The resist film is preferably washed with water, and dried after development using the developer.

### EXAMPLES

The embodiments of the invention are further described below by way of examples. Note that the invention is not limited to the following examples.

The sensitivity, MEEF, and LWR of the radiation-sensitive resin compositions obtained in the examples and the comparative examples were evaluated as follows.

### Sensitivity

A substrate (wafer) on which an ARC 29A (manufactured by Nissan Chemical Industries, Ltd.) film (thickness: 77 nm) was formed was used. The composition was spin-coated onto the substrate, and subjected to SB on a hot plate at a temperature shown in Table 2 for 90 seconds to form a resist film (thickness: 120 nm). The resist film was exposed through a mask pattern using a full-field reduction projection aligner (“S306C” manufactured by Nikon Corporation, numerical aperture: 0.78). After performing PEB at a temperature shown in Table 2 for 90 seconds, the resist film was developed at 25° C. for 60 seconds using a 2.38 mass % TMAH aqueous solution, washed with water, and dried to form a positive-tone resist pattern. An optimum dose (mJ/cm²) at which a 1:1 line-and-space (1L/1S) pattern having a line width of 90 nm was formed using a 1:1 line-and-space mask having a line width of 90 nm was taken as the sensitivity.

### LWR

The line width of a 90 nm 1L/1S pattern resolved at the optimum dose was observed from above at an arbitrary ten points using a scanning electron microscope (SEM) (“S9220” manufactured by Hitachi, Ltd.), and a variation (3σ) in line width was taken as the LWR. A small LWR indicates low roughness.

### MEEF

The optimum dose sensitivity was measured so that a 90 nm 1L/1S pattern was formed using a mask having a line width of 90 nm. The dimension of the pattern resolved at the optimum dose sensitivity using each mask (85.0 nm, 87.5 nm, 90.0 nm, 92.5 nm, and 95.0 nm) was measured. The mask size (horizontal axis) and the line width (vertical axis) were plotted on a graph, and the slope calculated by the least-square method was taken as the MEEF.

### <Resin Synthesis Example>

A monomer solution was prepared by dissolving 37.28 g (40 mol %) of a compound (S-1), 18.50 g (15 mol %) of a compound (S-2), and 44.22 g (45 mol %) of a compound (S-3) in 200 g of 2-butanone, and adding 4.83 g of dimethyl 2,2′-azobis(isobutyrate) to the solution. A three-necked flask (1000 ml) charged with 100 g of 2-butanone was purged with nitrogen for 30 minutes, and heated to 80° C. with stirring. The monomer solution was added dropwise to the flask using a dropping funnel over three hours. The monomers were polymerized for six hours from the start of addition of the monomer solution. The polymer solution was cooled with water to 30° C. or less, and poured into 2000 g of n-heptane. A white powdery precipitate was collected by filtration. The white powder thus collected was dispersed in (washed with) 400 g of n-heptane, and filtered off. This operation was repeated once. The powder was then dried at 50° C. for 17 hours to obtain a white powdery copolymer (resin (B-1)). The copolymer had an Mw of 9000 and an Mw/Mn ratio of 1.7. As a result of ¹³C-NMR analysis, it was found that the ratio of repeating units derived from the compounds (S-1), (S-2), and (S-3) contained in the copolymer was 45.4:11.3:43.3 (mol %). This copolymer is referred to as a polymer (B-1).

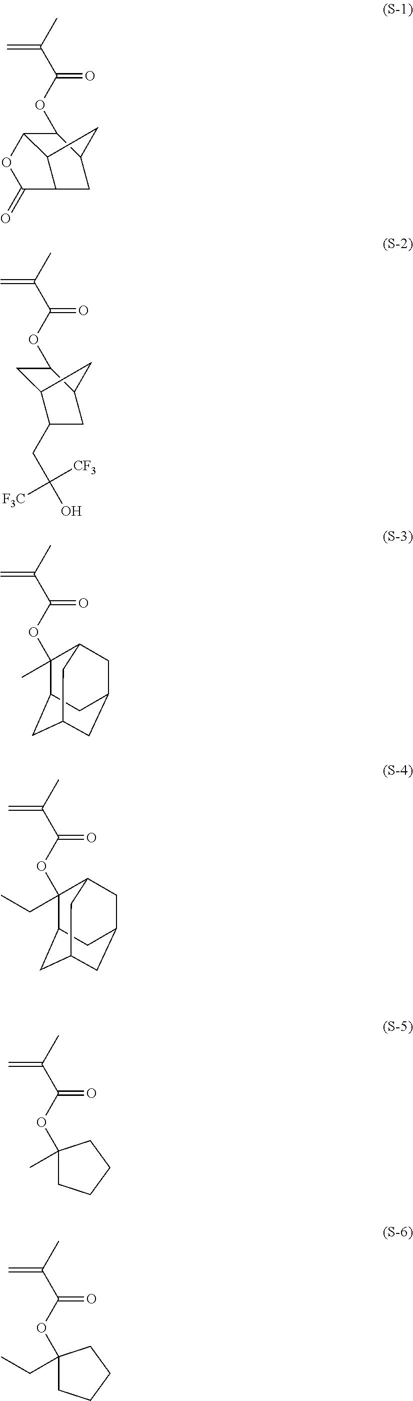

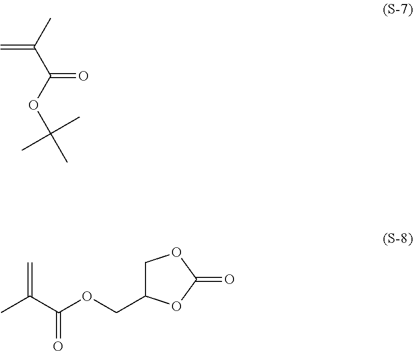

### Example 1

100 parts of the polymer (B-1), 10.1 parts of a photoacid generator (acid generator) (A-1), and 0.6 parts of an acid diffusion controller (C) were mixed to obtain a radiation-sensitive resin composition. The radiation-sensitive resin composition was dissolved in 1880 parts of a solvent (D-1) to obtain a radiation-sensitive resin composition solution. Note that the amount of each solvent is indicated by the mass ratio (parts by mass) relative to 100 parts of the polymer (B). The radiation-sensitive resin composition solution was evaluated as described above (SB=100° C., PEB=115° C.). The radiation-sensitive resin composition solution had a sensitivity of 38.0 mJ/cm², an LWR of 7.2 nm, and an MEEF of 3.0.

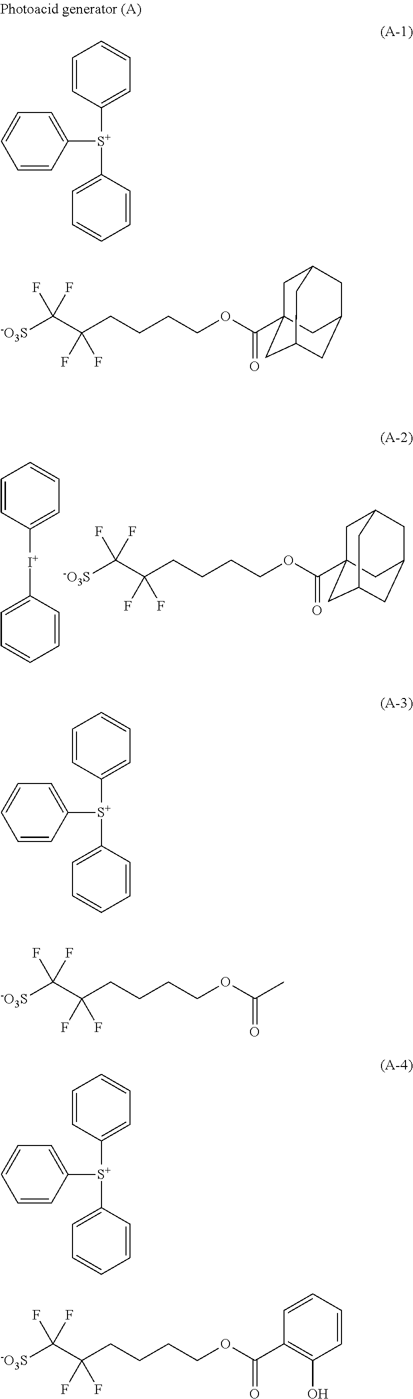

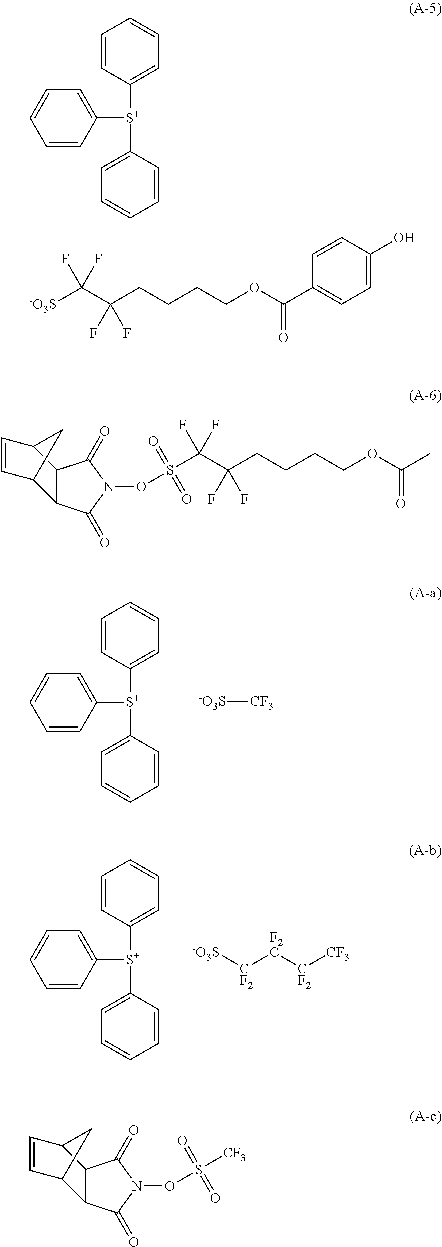

### Acid Diffusion Controller (C)

(C-1): trioctylamine
(C-2): N-t-butoxycarbonyl-4-hydroxypiperidine
(C-3): 2-phenylbenzimidazole
(C-4): triphenylsulfonium salicylate

### Solvent (D)

(D-1): propylene glycol monomethyl ether acetate
(D-2): cyclohexanone
(D-3): γ-butyrolactone

Polymers (resins (B)) (B-2) to (B-4) were produced in the same manner as the polymer (B-1), except for changing the molar ratio of the compounds (S-1) and the like as indicated in the section entitled “Copolymer (resin (B))”, and polymers (B-5) to (B-11) were produced in the same manner as the polymer (B-1), except for using methanol instead of heptane, and changing the molar ratio of the compounds (S-1) and the like as indicated in the section entitled “Copolymer (resin (B))”. Radiation-sensitive resin compositions (Examples 2 to 18 and Comparative Examples 1 to 10) were produced in the same manner as in Example 1, except for mixing each of the polymers (B-2) to (B-11), the photoacid generator (A), and the acid diffusion controller (C) in a ratio shown in Table 1. The resulting radiation-sensitive resin composition was dissolved in the solvent (D) (the mixing ratio is shown in Table 1) to obtain a radiation-sensitive resin composition solution. In Table 1, the term “resin” refers to “copolymer (resin (B))”. The resulting radiation-sensitive resin composition solution was subjected to the above measurements. The results are shown in Table 2.

### Copolymer (Resin (B))

B-2: (S-1) 40/(S-2) 15/(S-5) 45=41.0/12.8/46.2 (molar ratio), Mw=10500, Mw/Mn=1.7
B-3: (S-1) 40/(S-3) 30/(S-5) 30=43.2/27.8/29.0 (molar ratio), Mw=6000, Mw/Mn=1.4
B-4: (S-1) 40/(S-3) 60=56.2/53.8 (molar ratio), Mw=4000, Mw/Mn=1.4
B-5: (S-1) 40/(S-4) 60=58.2/51.8 (molar ratio), Mw=4000, Mw/Mn=1.4
B-6: (S-1) 50/(S-3) 25/(S-6) 25=54.9/25.4/19.6 (molar ratio), Mw=6000, Mw/Mn=1.7
B-7: (S-1) 50/(S-5) 25/(S-7) 25=53.5/23.9/22.6 (molar ratio), Mw=7000, Mw/Mn=1.3
B-8: (S-1) 50/(S-5) 50=49.1/50.9 (molar ratio), Mw=7000, Mw/Mn=1.7
B-9: (S-1) 50/(S-6) 50=48.6/51.4 (molar ratio), Mw=7000, Mw/Mn=1.7
B-10: (S-1) 40/(S-4) 10/(S-5) 40/(S-8) 10=33.7/12.8/9.6/43.8 (molar ratio), Mw=6000, Mw/Mn=1.5
B-11: (S-1) 40/(S-5) 60=43.1/56.9 (molar ratio), Mw=7000, Mw/Mn=1.4

TABLE 1

| | | | Acid | | |
|---|---|---|---|---|---|
| | | | generator | Acid diffusion | |
| | | Resin (parts) | (parts) | controller (parts) | Solvent (parts) |
| Example | 1 | B-1 (100) | A-1 (10.1) | C-1 (0.6) | D-1 (1880) |
| | 2 | B-2 (100) | A-2 (10.4) | C-1 (0.6) | D-1 (1880) |
| | 3 | B-2 (100) | A-3 (8.3) | C-1 (0.6) | D-1 (1880) |
| | 4 | B-1 (100) | A-4 (9.5) | C-1 (0.6) | D-1 (1880) |
| | 5 | B-2 (100) | A-6 (8.0) | C-1 (0.6) | D-1 (1880) |
| | 6 | B-1 (100) | A-5 (9.5) | C-1 (0.6) | D-1 (1880) |
| | 7 | B-3 (100) | A-1 (10.1) | C-2 (0.7) | D-1 (1880), D-2 (800), |
| | | | | | D-3 (30) |
| | 8 | B-4 (100) | A-1 (10.1) | C-2 (0.7) | D-1 (1880), D-2 (800), |
| | | | | | D-3 (30) |
| | 9 | B-5 (100) | A-1 (10.1) | C-2 (0.7) | D-1 (1880), D-2 (800), |
| | | | | | D-3 (30) |
| | 10 | B-6 (100) | A-1 (12.2) | C-2 (0.7) | D-1 (1100), D-2 (460), |
| | | | | | D-3 (30) |
| | 11 | B-7 (100) | A-1 (10.1) | C-2 (0.7) | D-1 (1880), D-2 (800), |
| | | | | | D-3 (30) |
| | 12 | B-8 (100) | A-1 (10.1) | C-2 (0.7) | D-1 (1880), D-2 (800), |
| | | | | | D-3 (30) |
| | 13 | B-9 (100) | A-1 (10.1) | C-2 (0.7) | D-1 (1880), D-2 (800), |
| | | | | | D-3 (30) |
| | 14 | B-9 (100) | A-1 (12.2) | C-3 (1.6) | D-1 (1880), D-2 (800), |
| | | | | | D-3 (30) |
| | 15 | B-8 (100) | A-1 (10.8) | C-4 (4.5) | D-1 (2400), D-2 (1000), |
| | | | | | D-3 (30) |
| | 16 | B-10 (100) | A-1 (8.2) | C-4 (4.5) | D-1 (1900), D-2 (800), |
| | | | | | D-3 (30) |
| | 17 | B-9 (100) | A-1 (12.2) | C-2 (1.6) | D-1 (1900), D-2 (800), |
| | | | | | D-3 (30) |
| | 18 | B-11 (100) | A-1 (12.2) | C-2 (1.6) | D-1 (1900), D-2 (800), |
| | | | | | D-3 (30) |
| Comparative | 1 | B-1 (100) | A-b (8.4) | C-1 (0.6) | D-1 (1880) |
| Example | 2 | B-2 (100) | A-c (6.0) | C-1 (0.6) | D-1 (1880) |
| | 3 | B-1 (100) | A-a (6.1) | C-1 (0.6) | D-1 (1880) |
| | 4 | B-3 (100) | A-b (8.4) | C-2 (0.7) | D-1 (1500), D-2 (650), |
| | | | | | D-3 (30) |
| | 5 | B-4 (100) | A-b (8.4) | C-2 (0.7) | D-1 (1500), D-2 (650), |
| | | | | | D-3 (30) |
| | 6 | B-5 (100) | A-b (8.4) | C-2 (0.7) | D-1 (1500), D-2 (650), |
| | | | | | D-3 (30) |
| | 7 | B-6 (100) | A-b (10.1) | C-2 (0.7) | D-1 (1500), D-2 (650), |
| | | | | | D-3 (30) |
| | 8 | B-7 (100) | A-b (8.4) | C-2 (0.7) | D-1 (1500), D-2 (650), |
| | | | | | D-3 (30) |
| | 9 | B-8 (100) | A-b (8.4) | C-2 (0.7) | D-1 (1500), D-2 (650), |
| | | | | | D-3 (30) |
| | 10 | B-9 (100) | A-b (8.4) | C-2 (0.7) | D-1 (1500), D-2 (650), |
| | | | | | D-3 (30) |

TABLE 2

| | | SB | PEB | Sensitivity | LWR | |
|---|---|---|---|---|---|---|
| | | (° C.) | (° C.) | (mJ/cm²) | (nm) | MEEF |
| Example | 1 | 100 | 115 | 38 | 7.2 | 3.0 |
| | 2 | 100 | 130 | 45 | 6.8 | 3.1 |
| | 3 | 100 | 105 | 32 | 6.9 | 2.8 |
| | 4 | 100 | 115 | 39 | 7.4 | 3.3 |
| | 5 | 90 | 130 | 57 | 7.2 | 3.2 |
| | 6 | 100 | 105 | 38 | 7.1 | 2.9 |
| | 7 | 100 | 110 | 41 | 7.1 | 2.5 |
| | 8 | 100 | 105 | 45 | 7.2 | 2.3 |
| | 9 | 100 | 85 | 43 | 6.9 | 2.8 |
| | 10 | 100 | 105 | 38 | 6.8 | 2.9 |
| | 11 | 100 | 130 | 33 | 7.2 | 2.2 |
| | 12 | 100 | 125 | 42 | 6.6 | 3.3 |
| | 13 | 100 | 100 | 38 | 6.8 | 3.2 |
| | 14 | 100 | 105 | 58 | 6.5 | 3.3 |
| | 15 | 100 | 105 | 37 | 6.1 | 2.3 |
| | 16 | 100 | 100 | 42 | 5.8 | 2.1 |
| | 17 | 100 | 105 | 46 | 6.3 | 3.3 |
| | 18 | 100 | 110 | 51 | 6.7 | 3.1 |
| Comparative | 1 | 100 | 115 | 36 | 8.2 | 3.8 |
| Example | 2 | 90 | 130 | 55 | 9.0 | 4.6 |
| | 3 | 100 | 105 | 20 | 7.2 | 6.6 |
| | 4 | 100 | 110 | 39 | 8.2 | 4.5 |
| | 5 | 100 | 105 | 43 | 9.1 | 4.7 |
| | 6 | 100 | 85 | 38 | 8.3 | 4.9 |
| | 7 | 100 | 105 | 36 | 8.1 | 4.3 |
| | 8 | 100 | 130 | 34 | 8.8 | 4.1 |
| | 9 | 100 | 125 | 42 | 7.3 | 4.9 |
| | 10 | 100 | 100 | 38 | 7.4 | 5.0 |

As shown in Table 2, the compositions of the examples exhibited an excellent MEEF as compared with the compositions of the comparative examples.

The sensitivity, MEEF, and top loss of the radiation-sensitive resin compositions obtained in the following examples and comparative examples were evaluated as follows.

### Sensitivity

A substrate (wafer) on which an ARC 29A (manufactured by Nissan Chemical Industries, Ltd.) film (thickness: 77 nm) was formed was used. The composition was spin-coated onto the substrate, and subjected to SB on a hot plate at a temperature shown in Table 4 for 60 seconds to form a resist film (thickness: 90 nm). The resist film was exposed through a mask pattern using a full-field reduction projection aligner (“S306C” manufactured by Nikon Corporation, numerical aperture: 0.78). After performing PEB at a temperature shown in Table 4 for 60 seconds, the resist film was developed at 25° C. for 30 seconds using a 2.38 mass % TMAH aqueous solution, washed with water, and dried to form a positive-tone resist pattern. An optimum dose (mJ/cm²) at which a 1:1 line-and-space pattern having a line width of 75 nm was formed using a 1:1 line-and-space mask having a line width of 75 nm was taken as the sensitivity.

### MEEF

The optimum dose sensitivity was measured so that a 75 nm 1L/1S pattern was formed using a mask having a line width of 75 nm. The dimension of the pattern resolved at the optimum dose sensitivity using each mask (70.0 nm, 72.5 nm, 75.0 nm, 77.5 nm, and 80.0 nm) was measured. The mask size (horizontal axis) and the line width (vertical axis) were plotted on a graph, and the slope calculated by the least-square method was taken as the MEEF.

### Top Loss

The height of a 75 nm 1L/1S pattern resolved at the optimum dose was measured when observing the cross section of the pattern using a scanning electron microscope (SEM) (“S-4800” manufactured by Hitachi, Ltd.), and the measured value was subtracted from the initial thickness (90 nm) to evaluate the top loss.

### <Resin Synthesis Example>

A monomer solution was prepared by dissolving 58.72 g (60 mol %) of the compound (S-1) and 41.28 g (40 mol %) of the compound (S-3) in 200 g of 2-butanone, and adding 5.38 g of dimethyl 2,2′-azobis(isobutyrate) to the solution. A three-necked flask (1000 ml) charged with 100 g of 2-butanone was purged with nitrogen for 30 minutes, and heated to 80° C. with stirring. The monomer solution was added dropwise to the flask using a dropping funnel over three hours. The monomers were polymerized for six hours from the start of addition of the monomer solution. The polymer solution was cooled with water to 30° C. or less, and poured into 2000 g of n-heptane. A white powdery precipitate was collected by filtration. The white powder thus collected was dispersed in (washed with) 400 g of n-heptane, and filtered off. This operation was repeated once. The powder was then dried at 50° C. for 17 hours to obtain a white powdery copolymer (resin (B-12)). The copolymer had an Mw of 6300 and an Mw/Mn ratio of 1.63. As a result of ¹³C-NMR analysis, it was found that the ratio of repeating units derived from the compounds (S-1) and (S-3) contained in the copolymer was 61.7:38.3 (mol %). This copolymer is referred to as a polymer (B-12).

### Example 19

100 parts of the polymer (B-12), 7.5 parts of a photoacid generator (acid generator) (A-1), and 0.8 parts of an acid diffusion controller (C-5) were mixed to obtain a radiation-sensitive resin composition. 2050 parts of a solvent (D-1), 880 parts of a solvent (D-2), and 30 parts of a solvent (D-3) were mixed to prepare a mixed solvent. The radiation-sensitive resin composition was dissolved in the mixed solvent to obtain a radiation-sensitive resin composition solution. Note that the amount of each solvent is indicated by the mass ratio (parts by mass) relative to 100 parts of the polymer (B-12). The radiation-sensitive resin composition solution was evaluated as described above (SB=100° C., PEB=110° C.). The radiation-sensitive resin composition solution had a sensitivity of 62.5 mJ/cm², an MEEF of 2.2, and a top loss of 7 nm.

### Photoacid Generator (A)

The above photoacid generators (A-1) to (A-5) and the following photoacid generator (P-1) were used as the photoacid generator (A).

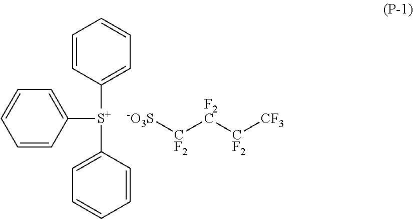

Acid Diffusion Controller (C)

(C-5): tert-butyl-4-hydroxy-1-piperidinecarboxylate

### Solvent (D)

(D-1): propylene glycol monomethyl ether acetate
(D-2): cyclohexanone
(D-3): γ-butyrolactone

Polymers (resins (B)) (B-13) to (B-18), (R-1), and (R-2) were produced in the same manner as the polymer (B-12), except for changing the molar ratio of the compounds (S-1) and the like as indicated in the section entitled “Copolymer (resin (B))”. Radiation-sensitive resin compositions (Examples 20 to 29 and Comparative Examples 11 and 12) were produced in the same manner as in Example 19, except for mixing each of the polymers (B-13) to (B-18), (R-1), and (R-2), the photoacid generator (A), and the acid diffusion controller (C) in a ratio shown in Table 3. The resulting radiation-sensitive resin composition was dissolved in the solvent (D) (the mixing ratio is shown in Table 3) to obtain a radiation-sensitive resin composition solution. In Table 3, the term “resin” refers to “copolymer (resin (B))”. The resulting radiation-sensitive resin composition solution was subjected to the above measurements. The measurement results are shown in Table 4.

### Copolymer (Resin (B))

B-13: (S-1) 60/(S-3) 25/(S-6) 15=60.2/24.3/15.5 (molar ratio), Mw6200, Mw/Mn=1.58
B-14: (S-1) 60/(S-3) 25/(S-5) 15=61.3/23.8/14.9 (molar ratio), Mw6400, Mw/Mn=1.66
B-15: (S-1) 60/(S-4) 40=62.3/37.7 (molar ratio), Mw7000, Mw/Mn=1.72
B-16: (S-1) 60/(S-4) 25/(S-6) 15=59.7/25.1/15.2 (molar ratio), Mw6600, Mw/Mn=1.59
B-17: (S-1) 60/(S-4) 25/(S-5) 15=60.4:24.2/15.4 (molar ratio), Mw5900, Mw/Mn=1.61
B-18: (S-1) 50/(S-4) 10/(S-5) 30/(S-9) 10=51.3/9.5/29.4/9.8 (molar ratio), Mw6700, Mw/Mn=1.63
R-1: (S-1) 40/(S-4) 60=40.4/59.6 (molar ratio), Mw6300, Mw/Mn=1.68
R-2: (S-1) 50/(S-3) 35/(S-6) 15=49.2/36.4/14.4 (molar ratio), Mw6700, Mw/Mn=1.65

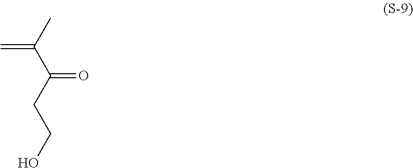

TABLE 3

| | | | Acid | | |
|---|---|---|---|---|---|
| | | Resin | generator | Acid diffusion | |
| | | (parts) | (parts) | controller (parts) | Solvent (parts) |
| Example | 19 | B-12 (100) | A-1 (10.1) | C-5 (0.8) | D-1 (2050), D-2 (880), |
| | | | | | D-3 (30) |
| | 20 | B-13 (100) | A-1 (10.1) | C-5 (0.8) | D-1 (2050), D-2 (880), |
| | | | | | D-3 (30) |
| | 21 | B-14 (100) | A-1 (10.1) | C-5 (0.8) | D-1 (2050), D-2 (880), |
| | | | | | D-3 (30) |
| | 22 | B-15 (100) | A-1 (10.1) | C-5 (0.8) | D-1 (2050), D-2 (880), |
| | | | | | D-3 (30) |
| | 23 | B-16 (100) | A-1 (10.1) | C-5 (0.8) | D-1 (2050), D-2 (880), |
| | | | | | D-3 (30) |
| | 24 | B-17 (100) | A-1 (10.1) | C-5 (0.8) | D-1 (2050), D-2 (880), |
| | | | | | D-3 (30) |
| | 25 | B-18 (100) | A-1 (10.1) | C-5 (0.8) | D-1 (2050), D-2 (880), |
| | | | | | D-3 (30) |
| | 26 | B-12 (100) | A-2 (10.4) | C-5 (0.8) | D-1 (2050), D-2 (880), |
| | | | | | D-3 (30) |
| | 27 | B-12 (100) | A-3 (8.3) | C-5 (0.8) | D-1 (2050), D-2 (880), |
| | | | | | D-3 (30) |
| | 28 | B-12 (100) | A-4 (9.5) | C-5 (0.8) | D-1 (2050), D-2 (880), |
| | | | | | D-3 (30) |
| | 29 | B-12 (100) | A-5 (9.5) | C-5 (0.8) | D-1 (2050), D-2 (880), |
| | | | | | D-3 (30) |
| Comparative | 11 | R-1 (100) | P-1 (8.4) | C-5 (0.8) | D-1 (2050), D-2 (880), |
| Example | | | | | D-3 (30) |
| | 12 | R-2 (100) | P-1 (8.4) | C-5 (0.8) | D-1 (2050), D-2 (880), |
| | | | | | D-3 (30) |

TABLE 4

| | | SB | PEB | Sensitivity | | Top loss |
|---|---|---|---|---|---|---|
| | | (° C.) | (° C.) | (mJ/cm²) | MEEF | (nm) |
| Example | 19 | 100 | 115 | 52.5 | 2.2 | 7 |
| | 20 | 100 | 110 | 48.5 | 2.5 | 9 |
| | 21 | 100 | 115 | 50.5 | 2.4 | 8 |
| | 22 | 100 | 100 | 46.5 | 2.3 | 9 |
| | 23 | 100 | 100 | 42.5 | 2.6 | 9 |
| | 24 | 100 | 105 | 38.5 | 2.5 | 9 |
| | 25 | 100 | 100 | 37.5 | 2.5 | 9 |
| | 26 | 100 | 115 | 51.0 | 2.3 | 8 |
| | 27 | 100 | 115 | 49.5 | 2.4 | 7 |
| | 28 | 100 | 115 | 47.5 | 2.3 | 8 |
| | 29 | 100 | 115 | 49.0 | 2.5 | 9 |
| Comparative | 11 | 100 | 100 | 37.5 | 3.9 | 21 |
| Example | 12 | 100 | 110 | 42.5 | 3.7 | 15 |

As shown in Table 4, the compositions of the examples had a low MEEF and a small top loss as compared with the compositions of the comparative examples.

The sensitivity, the LWR, and the film reduction amount of the radiation-sensitive resin compositions obtained in the following examples and comparative examples were evaluated as follows.

### Sensitivity

A substrate (wafer) on which an ARC 29A (manufactured by Nissan Chemical Industries, Ltd.) film (thickness: 77 nm) was formed was used. The composition was spin-coated onto the substrate, and subjected to SB on a hot plate at a temperature shown in Table 6 for 60 seconds to form a resist film (thickness: 90 nm). The resist film was exposed through a mask pattern using a full-field reduction projection aligner (“S306C” manufactured by Nikon Corporation, numerical aperture: 0.78). After performing PEB at a temperature shown in Table 6 for 60 seconds, the resist film was developed at 25° C. for 30 seconds using a 2.38 mass % TMAH aqueous solution, washed with water, and dried to form a positive-tone resist pattern. An optimum dose (mJ/cm²) at which a 1:1 line-and-space pattern having a line width of 75 nm was formed using a 1:1 line-and-space mask having a line width of 75 nm was taken as the sensitivity.

### LWR

A 75 nm 1L/1S pattern resolved at the optimum dose was observed from above. The line width of the pattern was measured at an arbitrary ten points, and a variation (36) in measured values was taken as the LWR.

### Top Loss

The height of a 75 nm 1L/1S pattern resolved at the optimum dose was measured when observing the cross section of the pattern using a scanning electron microscope (SEM) (“S-4800” manufactured by Hitachi, Ltd.), and the measured value was subtracted from the initial thickness (90 nm) to evaluate the top loss.

### <Resin Synthesis Example>

A monomer solution was prepared by dissolving 31.26 g (30 mol %) of the compound (S-1), 38.46 g (35 mol %) of the compound (S-3), 12.82 g (15 mol %) of the compound (S-6), and 17.46 g (45 mol %) of the compound (S-8) in 200 g of 2-butanone, and adding 3.85 g of dimethyl 2,2′-azobis(isobutyrate) to the solution. A three-necked flask (1000 ml) charged with 100 g of 2-butanone was purged with nitrogen for 30 minutes, and heated to 80° C. with stirring. The monomer solution was added dropwise to the flask using a dropping funnel over three hours. The monomers were polymerized for six hours from the start of addition of the monomer solution. The polymer solution was cooled with water to 30° C. or less, and poured into 2000 g of n-heptane. A white powdery precipitate was collected by filtration. The white powder thus collected was dispersed in (washed with) 400 g of n-heptane, and filtered off. This operation was repeated once. The powder was then dried at 50° C. for 17 hours to obtain a white powdery copolymer (resin (B-19)). The copolymer had an Mw of 6100 and an Mw/Mn ratio of 1.64. As a result of ¹³C-NMR analysis, it was found that the ratio of repeating units derived from the compounds (S-1), (S-3), (S-6), and (S-8) contained in the copolymer was 30.2:34.7:14.8:20.3 (mol %). This copolymer is referred to as a polymer (B-19).

### Example 30

100 parts of the polymer (B-19), 10.1 parts of a photoacid generator (acid generator) (A-1), and 0.8 parts of an acid diffusion controller (C-5) were mixed to obtain a radiation-sensitive resin composition. 2050 parts of a solvent (D-1), 880 parts of a solvent (D-2), and 30 parts of a solvent (D-3) were mixed to prepare a mixed solvent. The radiation-sensitive resin composition was dissolved in the mixed solvent to obtain a radiation-sensitive resin composition solution. Note that the amount of each solvent is indicated by the mass ratio (parts by mass) relative to 100 parts of the polymer (B-19). The radiation-sensitive resin composition solution was evaluated as described above (SB=100° C., PEB=105° C.). The radiation-sensitive resin composition solution had a sensitivity of 41.0 mJ/cm², an LWR of 7.9 nm, and a film reduction amount of 9 nm.

### Photoacid Generator (A)

The above photoacid generators (A-1) to (A-5) and (P-1) were used as the photoacid generator (A).

### Acid Diffusion Controller

(C-5): tert-butyl-4-hydroxy-1-piperidinecarboxylate

### Solvent

(D-1): propylene glycol monomethyl ether acetate
(D-2): cyclohexanone
(D-3): γ-butyrolactone

Polymers (resins (B)) (B-20) to (B-24) and (R-3) to (R-5) were produced in the same manner as the polymer (B-19), except for changing the molar ratio of the compounds (S-1) and the like as indicated in the section entitled “Copolymer (resin (B))”. Radiation-sensitive resin compositions (Examples 31 to 39 and Comparative Examples 13 to 16) were produced in the same manner as in Example 30, except for mixing each of the polymers (B-20) to (B-24) and (R-3) to (R-5), the photoacid generator (A), and the acid diffusion controller (C) in a ratio shown in Table 5. The resulting radiation-sensitive resin composition was dissolved in the solvent (D) (the mixing ratio is shown in Table 5) to obtain a radiation-sensitive resin composition solution. In Table 5, the term “resin” refers to “copolymer (resin (B))”. The resulting radiation-sensitive resin composition solution was subjected to the above measurements. The measurement results are shown in Table 6.

### Copolymer (Resin (B))

B-20: (S-1) 50/(S-4) 10/(S-5) 30/(S-8) 10=49.6/10.1/29.4/10.9 (molar ratio), Mw6400, Mw/Mn=1.59
B-21: (S-1) 40/(S-4) 10/(S-5) 40/(S-8) 10=41.2/9.9/39.3/9.6 (molar ratio), Mw6500, Mw/Mn=1.67
B-22: (S-1) 20/(S-3) 60/(S-8) 20=20.2/59.4/20.4 (molar ratio), Mw6900, Mw/Mn=1.71
B-23: (S-1) 30/(S-3) 50/(S-8) 20=29.8/50.4/19.8 (molar ratio), Mw6500, Mw/Mn=1.62
B-24: (S-1) 30/(S-5) 50/(S-8) 20=30.5/51.2/18.3 (molar ratio), Mw5800, Mw/Mn=1.63
R-3: (S-1) 50/(S-3) 35/(S-6) 15=49.2/36.4/14.4 (molar ratio), Mw6700, Mw/Mn=1.68
R-4: (S-1) 50/(S-4) 15/(S-5) 35=50.8/15.3/33.9 (molar ratio), Mw6200, Mw/Mn=1.74
R-5: (S-1) 40/(S-3) 60=41.8/58.2 (molar ratio), Mw6200, Mw/Mn=1.71

TABLE 5

| | | | Acid | | |
|---|---|---|---|---|---|
| | | Resin | generator | Acid diffusion | |
| | | (parts) | (parts) | controller (parts) | Solvent (parts) |
| Example | 30 | B-19 (100) | A-1 (10.1) | C-5 (0.8) | D-1 (2050), D-2 (880), |
| | | | | | D-3 (30) |
| | 31 | B-20 (100) | A-1 (10.1) | C-5 (0.8) | D-1 (2050), D-2 (880), |
| | | | | | D-3 (30) |
| | 32 | B-21 (100) | A-1 (10.1) | C-5 (0.8) | D-1 (2050), D-2 (880), |
| | | | | | D-3 (30) |
| | 33 | B-22 (100) | A-1 (10.1) | C-5 (0.8) | D-1 (2050), D-2 (880), |
| | | | | | D-3 (30) |
| | 34 | B-23 (100) | A-1 (10.1) | C-5 (0.8) | D-1 (2050), D-2 (880), |
| | | | | | D-3 (30) |
| | 35 | B-24 (100) | A-1 (10.1) | C-5 (0.8) | D-1 (2050), D-2 (880), |
| | | | | | D-3 (30) |
| | 36 | B-19 (100) | A-2 (10.4) | C-5 (0.8) | D-1 (2050), D-2 (880), |
| | | | | | D-3 (30) |
| | 37 | B-19 (100) | A-3 (8.3) | C-5 (0.8) | D-1 (2050), D-2 (880), |
| | | | | | D-3 (30) |
| | 38 | B-19 (100) | A-4 (9.5) | C-5 (0.8) | D-1 (2050), D-2 (880), |
| | | | | | D-3 (30) |
| | 39 | B-19 (100) | A-5 (9.5) | C-5 (0.8) | D-1 (2050), D-2 (880), |
| | | | | | D-3 (30) |
| Comparative | 13 | R-3 (100) | P-1 (8.4) | C-5 (0.8) | D-1 (2050), D-2 (880), |
| Example | | | | | D-3 (30) |
| | 14 | R-4 (100) | P-1 (8.4) | C-5 (0.8) | D-1 (2050), D-2 (880), |
| | | | | | D-3 (30) |
| | 15 | R-5 (100) | P-1 (8.4) | C-5 (0.8) | D-1 (2050), D-2 (880), |
| | | | | | D-3 (30) |
| | 16 | R-5 (100) | A-1 (10.1) | C-5 (0.8) | D-1 (2050), D-2 (880), |
| | | | | | D-3 (30) |

TABLE 6

| | | SB | PEB | Sensitivity | LWR | Top loss |
|---|---|---|---|---|---|---|
| | | (° C.) | (° C.) | (mJ/cm²) | (nm) | (nm) |
| Example | 30 | 100 | 105 | 41.0 | 7.9 | 9 |
| | 31 | 100 | 95 | 36.0 | 7.5 | 7 |
| | 32 | 100 | 95 | 34.5 | 7.2 | 8 |
| | 33 | 100 | 105 | 38.0 | 8.8 | 9 |
| | 34 | 100 | 105 | 39.5 | 8.9 | 8 |
| | 35 | 100 | 105 | 38.5 | 7.1 | 9 |
| | 36 | 100 | 105 | 40.0 | 7.7 | 8 |
| | 37 | 100 | 105 | 39.5 | 7.9 | 8 |
| | 38 | 100 | 105 | 38.0 | 7.8 | 8 |
| | 39 | 100 | 105 | 39.5 | 7.7 | 9 |
| Comparative | 13 | 100 | 115 | 42.5 | 9.8 | 15 |
| Example | 14 | 100 | 100 | 37.5 | 9.3 | 17 |
| | 15 | 100 | 115 | 39.0 | 10.1 | 18 |
| | 16 | 100 | 115 | 38.0 | 9.0 | 13 |

As shown in Table 6, the compositions of the examples had small LWR and a small top loss as compared with the compositions of the comparative examples.

According to the embodiment of the present invention, the radiation-sensitive resin composition can form a resist film that generates an acid that does not vaporize and has a moderately small diffusion length upon exposure, has a low MEEF, and produces a resist pattern having excellent surface/sidewall flatness (roughness).

The radiation-sensitive resin composition according to the embodiment of the invention may suitably be used as a chemically-amplified resist. The radiation-sensitive resin composition according to the embodiment of the invention may be used as a chemically-amplified resist that is used for lithography utilizing an ArF excimer laser as a light source, and exhibits a moderate sensitivity, small LWR, and a low MEEF when forming a fine pattern having a line width of 90 nm or less.

Obviously, numerous modifications and variations of the present invention are possible in light of the above teachings. It is therefore to be understood that within the scope of the appended claims, the invention may be practiced otherwise than as specifically described herein.

1. A radiation-sensitive resin composition comprising:
a sulfonate or sulfonic acid group-containing photoacid generator including a partial structure shown by a following formula (1); and
a resin, 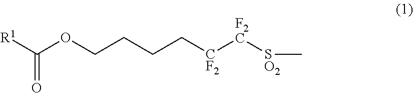
wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms.

2. The radiation-sensitive resin composition according to claim 1, wherein the photoacid generator comprises a compound shown by a following formula (2), 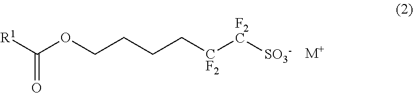
wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms, and M⁺ represents a monovalent onium cation.

3. The radiation-sensitive resin composition according to claim 2, wherein M⁺ represents a sulfonium cation shown by a following formula (3) or an iodonium cation shown by a following formula (4), 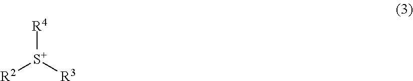
wherein each of R², R³, and R⁴ represents either one of a substituted or unsubstituted linear or branched alkyl group having 1 to 10 carbon atoms and a substituted or unsubstituted aryl group having 6 to 18 carbon atoms, or at least two of R², R³, and R⁴ bond to form a ring with the sulfur atom,
R⁵—I⁺—R⁶ (4)
wherein each of R⁵ and R⁶ represents either one of a substituted or unsubstituted linear or branched alkyl group having 1 to 10 carbon atoms and a substituted or unsubstituted aryl group having 6 to 18 carbon atoms, or R⁵ and R⁶ bond to form a ring with the iodine atom.

4. The radiation-sensitive resin composition according to claim 1, wherein the photoacid generator comprises a compound shown by a following formula (5), 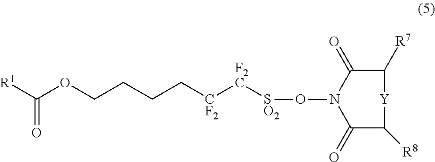
wherein R¹ represents a substituted or unsubstituted linear or branched monovalent hydrocarbon group having 1 to 30 carbon atoms, a substituted or unsubstituted cyclic or partially cyclic monovalent hydrocarbon group having 3 to 30 carbon atoms, a substituted or unsubstituted aryl group having 6 to 30 carbon atoms, or a substituted or unsubstituted cyclic monovalent organic group having 4 to 30 carbon atoms, each of R⁷ and R⁸ represents either one of a hydrogen atom and a substituted or unsubstituted monovalent organic group, or R⁷ and R⁸ bond to form a ring with the carbon atoms bonded thereto, and Y represents a single bond, a double bond, or a divalent organic group.

5. The radiation-sensitive resin composition according to claim 1, wherein the resin includes a first repeating unit shown by a following formula (6), 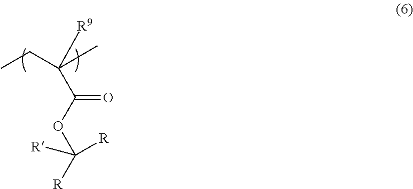
wherein R⁹ represents a hydrogen atom, a methyl group, or a trifluoromethyl group, R′ represents a linear or branched alkyl group having 1 to 4 carbon atoms, and each of R represents a linear or branched alkyl group having 1 to 4 carbon atoms and a monovalent alicyclic hydrocarbon group having 4 to 20 carbon atoms, or R bond to form a divalent alicyclic hydrocarbon group having 4 to 20 carbon atoms together with the carbon atom bonded thereto.

6. The radiation-sensitive resin composition according to claim 5, wherein the first repeating unit shown by the formula (6) comprises at least one of a second repeating unit shown by a following formula (6-1), a third repeating unit shown by a following formula (6-2), and a fourth repeating unit shown by a following formula (6-3), 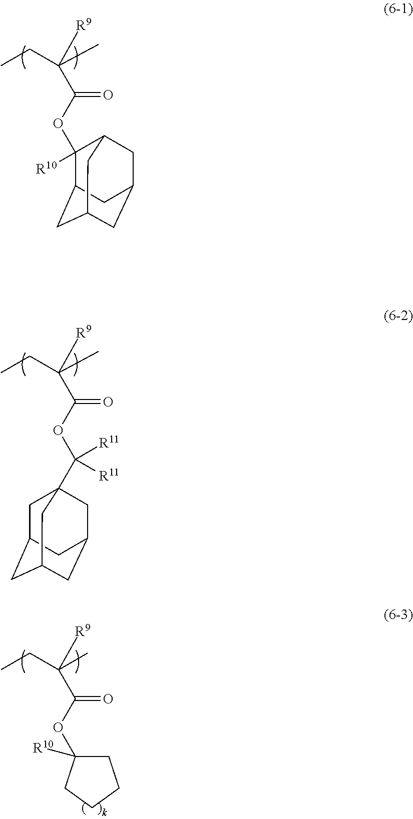
wherein R⁹ represents a hydrogen atom, a methyl group, or a trifluoromethyl group, R¹⁰ represents a linear or branched alkyl group having 1 to 4 carbon atoms, R¹¹ individually represent a linear or branched alkyl group having 1 to 4 carbon atoms, and k is an integer from 0 to 4.

7. The radiation-sensitive resin composition according to claim 5, wherein the resin further includes at least one of fifth to tenth repeating units shown by following formulas (7-1) to (7-6), 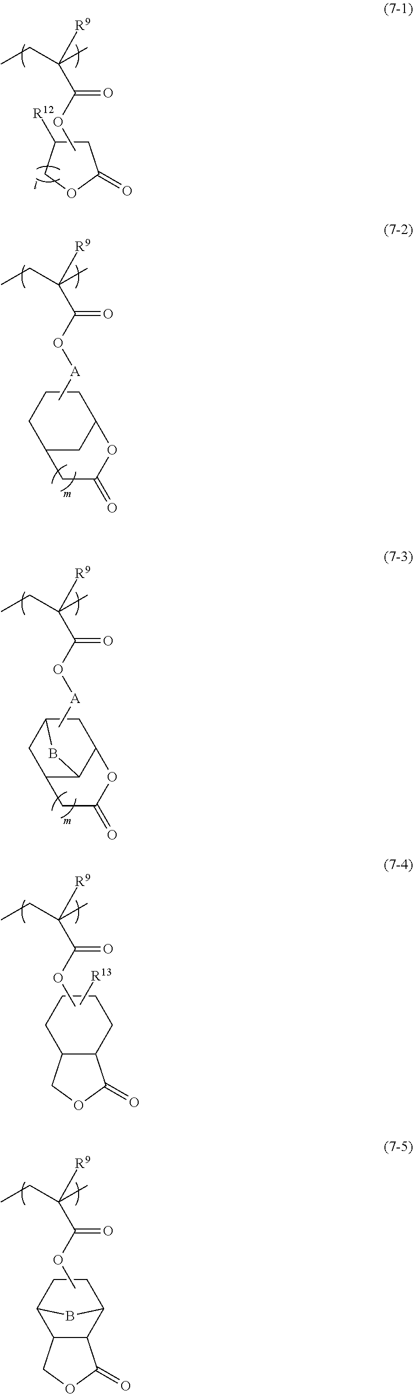 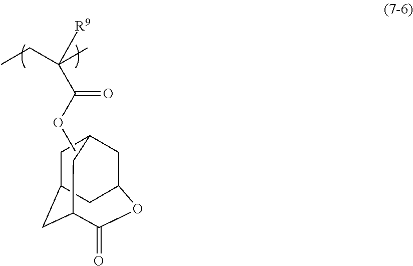
wherein R⁹ represents a hydrogen atom, a methyl group, or a trifluoromethyl group, R¹² represents a hydrogen atom or a substituted or unsubstituted alkyl group having 1 to 4 carbon atoms, R¹³ represents a hydrogen atom or a methoxy group, A represents a single bond or a methylene group, B represents an oxygen atom or a methylene group, 1 is an integer from 1 to 3, and m is 0 or 1.

8. The radiation-sensitive resin composition according to claim 5, wherein the resin further includes a eleventh repeating unit shown by a following formula (7-7), 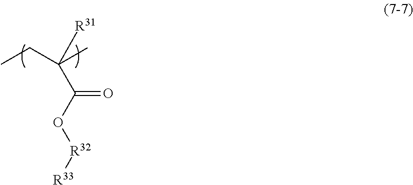
wherein R³¹ represents a hydrogen atom, a fluorine atom, an alkyl group having 1 to 4 carbon atoms, or a fluoroalkyl group having 1 to 4 carbon atoms, R³² represents a single bond or a divalent hydrocarbon group having 1 to 8 carbon atoms, and R³³ represents a monovalent group having a structure shown by a following formula (1), 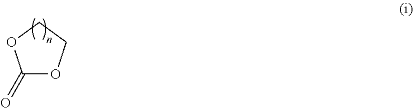
wherein n is 1 or 2.

9. The radiation-sensitive resin composition according to claim 1, further comprising:
an acid diffusion controller.

10. The radiation-sensitive resin composition according to claim 9, wherein the acid diffusion controller comprises a compound shown by a following formula (11), 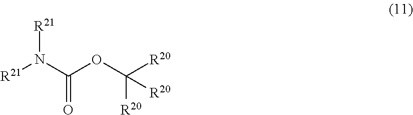
wherein each of R²⁰ and R²¹ represents either one of a hydrogen atom, a substituted or unsubstituted linear, branched, or cyclic alkyl group having 1 to 20 carbon atoms, an aryl group, and an aralkyl group, or R²⁰ or R²¹ bond to form a saturated or unsaturated divalent hydrocarbon group having 4 to 20 carbon atoms, or a derivative thereof, together with the carbon atom bonded thereto.

11. The radiation-sensitive resin composition according to claim 9, wherein the acid diffusion controller comprises a compound shown by a following formula (12),
X⁺Z⁻ (12)
wherein X⁺ represents a cation shown by a following formula (12-1) or (12-2), and Z⁻ represents an anion shown by OH⁻, R²²—COO⁻, or R²²—SO₃⁻ (wherein R²² represents a substituted or unsubstituted alkyl group or a substituted or unsubstituted aryl group), 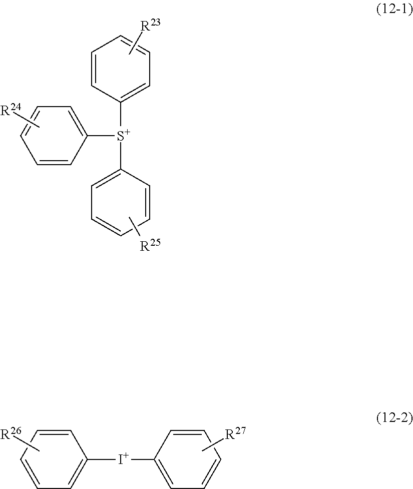
wherein each of R²³, R²⁴, and R²⁵ represents either one of a hydrogen atom, an alkyl group, an alkoxy group, a hydroxyl group, and a halogen atom, and each of R²⁶ and R²⁷ represents either one of a hydrogen atom, an alkyl group, an alkoxy group, a hydroxyl group, and a halogen atom.

12. The radiation-sensitive resin composition according to claim 2, wherein the resin includes acid-dissociable group-containing repeating units in an amount of 25 to 40 mol %.
